(19) United States
(12) Patent Application Publication
(10) Pub. No.: US 2026/0353915 A1
(43) Pub. Date: Nov. 5, 2026

(54) LIGHT-EMITTING DEVICE AND MANUFACTURING METHOD THEREOF, DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventor: Dong Li, Beijing (CN)

(21) Appl. No.: 18/856,215

(22) PCT Filed: Dec. 11, 2023
(86) PCT No.: PCT/CN2023/137891

§ 371 Date: Oct. 11, 2024

(51) Int. Cl. H10K 50/16; C09K 11/02; C09K 113/00; H10K 50/115; H10K 71/40; H10K 85/30

(52) U.S. Cl. CPC H10K 50/166; C09K 11/025; H10K 50/115; H10K 71/441; H10K 85/381; C09K 2113/00

(57) ABSTRACT

The present disclosure provides a light-emitting device, a manufacturing method thereof and a display device. The light-emitting device includes a first electrode, a quantum dot light-emitting layer, an electron transport layer on a side of the quantum dot light-emitting layer away from the first electrode, and a protective layer on the side of the quantum dot light-emitting layer away from the first electrode. The quantum dot light-emitting layer includes organic acid groups, and the protective layer blocks the organic acid groups from contacting with the electron transport layer.

### TECHNICAL FIELD

The present disclosure relates to the field of display technology, and in particular, to a light-emitting device, a manufacturing method thereof, and a display device comprising the light-emitting device.

### BACKGROUND

Light-Emitting Diode (LED) emits light by releasing energy through the recombination of electrons and holes. Light-emitting diodes comprise, but are not limited to, organic light-emitting diodes (OLED) and quantum dot light-emitting diodes (QLED). Quantum dots are semiconductor nanomaterials that can bind excitons in three dimensions. Quantum dots have great application potential in high quality displays due to their excellent characteristics such as high quantum efficiency, narrow excitation spectrum, high photostability, long fluorescence lifetime and good solution processing compatibility. Quantum dot light-emitting diode is a device using quantum dots as light-emitting materials. Compared with organic light-emitting diodes, it has outstanding advantages such as lower energy consumption, higher color purity and wider color gamut, therefore quantum dot light-emitting technology has become the most potential next-generation self-luminous display technology.

### SUMMARY

According to an aspect of the present disclosure, a light-emitting device is provided. The light-emitting device comprises: a first electrode; a quantum dot light-emitting layer; an electron transport layer on a side of the quantum dot light-emitting layer away from the first electrode; and a protective layer on the side of the quantum dot light-emitting layer away from the first electrode, wherein the quantum dot light-emitting layer comprises organic acid groups, and the protective layer blocks the organic acid groups from contacting with the electron transport layer.

In some embodiments, the protective layer is at least between the quantum dot light-emitting layer and the electron transport layer.

In some embodiments, the protective layer is further in the electron transport layer.

In some embodiments, the protective layer is in a side of the electron transport layer close to the quantum dot light-emitting layer, and the protective layer is in contact with the quantum dot light-emitting layer.

In some embodiments, the protective layer comprises an anti-contact layer or a salt layer.

In some embodiments, the salt layer comprises a carboxylate layer or a quaternary amine salt layer.

In some embodiments, the salt layer further comprises unreacted alkali.

In some embodiments, a material of the anti-contact layer comprises any one of a hydrophobic material, a silane coupling agent and an epoxy resin.

In some embodiment, the salt layer is in physical contact with the electron transport layer.

In some embodiments, the salt layer is connected with the electron transport layer through a chemical bond.

In some embodiments, the electron transport layer comprises a ZnO body and a first coordination group coordinated on the ZnO body, and the salt layer is connected with at least some first coordination groups through the chemical bond.

In some embodiments, the electron transport layer comprises a first surface close to the quantum dot light-emitting layer and a second surface away from the quantum dot light-emitting layer, the salt layer is connected with the first coordination group at the first surface through the chemical bond, and the second surface comprises a first ligand coordinated on the ZnO body, and the first ligand comprises a basic group.

In some embodiments, the general chemical formula of the first ligand is

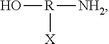

wherein the group R represents an alkyl chain, and the group X is selected from any one of the following:

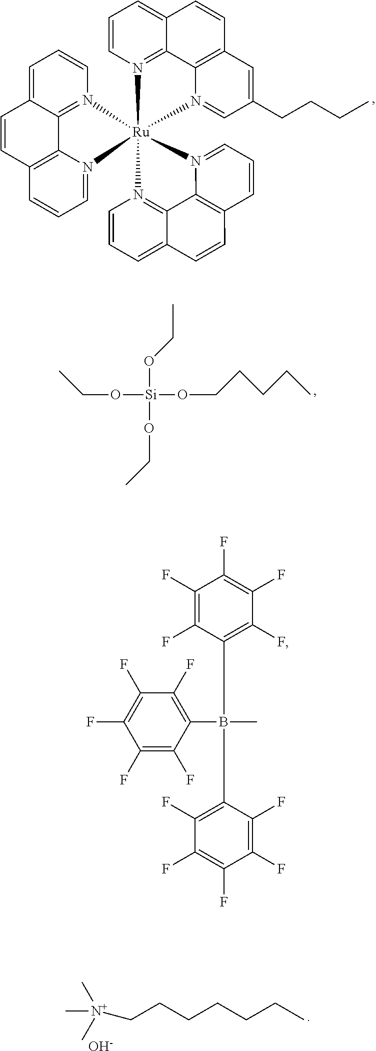

In some embodiments, the protective layer comprises a surfactant, and the surfactant encapsulates the electron transport layer.

In some embodiments, the electron transport layer comprises zinc oxide nanoparticles, and the protective layer comprises a surfactant, and the surfactant encapsulates the zinc oxide nanoparticles.

In some embodiments, the general chemical formula of the surfactant is A⁺B⁻, wherein A⁺ represents cation and B⁻ represents anion, wherein B⁻ is selected from any one of halogen ions, hydroxide ions, PF6⁻ and BF4⁻; and wherein the general chemical formula of A⁺ is CₙH₂ₙ₊₁N(CₘH₂ₘ₊₁)₃ or CₙH₂ₙ₊₁N (CₘH₂ₘ₊₁)₂(CₘH₂ₘ₊₁)₂NCₙH₂ₙ₊₁, where n is any positive integer between 8 and 20 and m is any positive number between 0 and 4.

In some embodiments, the quantum dot light-emitting layer comprises a plurality of quantum dots, at least some quantum dots of the plurality of quantum dots each comprise quantum a dot body and a second ligand coordinated on the quantum dot body, and at least some second ligands are the organic acid groups.

In some embodiments, the general chemical formula of the organic acid group is CₙH₂ₙ₋₁COOH or C₆H₅—CₙH₂ₙ—COOH, and n is a positive integer greater than or equal to 1.

In some embodiments, the light-emitting device further comprises a hole injection layer between the first electrode and the quantum dot light-emitting layer; a hole transport layer between the hole injection layer and the quantum dot light-emitting layer; and a second electrode on a side of the electron transport layer away from the first electrode.

In some embodiments, the quantum dot light-emitting layer comprises a plurality of quantum dots, at least some quantum dots of the plurality of quantum dots each comprise a quantum dot body and a plurality of second ligands coordinated on the quantum dot body, a part of the second ligands in the plurality of second ligands are the organic acid groups, and the quantum dot light-emitting layer comprises a red quantum dot light-emitting layer configured to emit red light, a green quantum dot light-emitting layer configured to emit green light, and a blue quantum dot light-emitting layer configured to emit blue light, wherein the red quantum dot light-emitting layer, the green quantum dot light-emitting layer, and the green quantum dot light-emitting layer are separated from each other, and the molar ratio of the organic acid groups in the red quantum dot light-emitting layer to the plurality of second ligands in the red quantum dot light-emitting layer is smaller than the molar ratio of the organic acid groups in the green quantum dot light-emitting layer to the plurality of second ligands in the green quantum dot light-emitting layer, and the molar ratio of organic acid groups in the green quantum dot light-emitting layer to the plurality of second ligands in the green quantum dot light-emitting layer is smaller than the molar ratio of organic acid groups in the blue quantum dot light-emitting layer to the plurality of second ligands in the blue quantum dot light-emitting layer.

In some embodiments, the molar ratio of organic acid groups in the red quantum dot light-emitting layer to the plurality of second ligands in the red quantum dot light-emitting layer is 0.1%-10%, the molar ratio of organic acid groups in the green quantum dot light-emitting layer to the plurality of second ligands in the green quantum dot light-emitting layer is 0.1%-20%, the molar ratio of organic acid groups in the blue quantum dot light-emitting layer to the plurality of second ligands in the blue quantum dot light-emitting layer is 0.1%-60%.

In some embodiments, the protective layer is between the quantum dot light-emitting layer and the electron transport layer, and the protective layer comprises a first protective layer, a second protective layer and a third protective layer, and an orthographic projection of the first protective layer on the first electrode at least partially overlaps with an orthographic projection of the red quantum dot light-emitting layer on the first electrode, an orthographic projection of the second protective layer on the first electrode at least partially overlaps with an orthographic projection of the green quantum dot light-emitting layer on the first electrode, and an orthographic projection of the third protective layer on the first electrode at least partially overlaps with an orthographic projection of the blue quantum dot light-emitting layer on the first electrode, a thickness of the first protective layer is greater than a thickness of the second protective layer, and the thickness of the second protective layer is greater than a thickness of the third protective layer.

In some embodiments, the electron transport layer comprises a hydrophobic material or an alkaline material, the electron transport layer comprises a first electron transport layer, a second electron transport layer and a third electron transport layer, and an orthographic projection of the first electron transport layer on the first electrode at least partially overlaps with an orthographic projection of the red quantum dot light-emitting layer on the first electrode, an orthographic projection of the second electron transport layer on the first electrode at least partially overlaps with an orthographic projection of the green quantum dot light-emitting layer on the first electrode, an orthographic projection of the third electron transport layer on the first electrode at least partially overlaps with an orthographic projection of the blue quantum dot light-emitting layer on the first electrode, a content of hydrophobic material or alkaline material in the first electron transport layer is greater than a content of hydrophobic material or alkaline material in the second electron transport layer, and the content of hydrophobic material or alkaline material in the second electron transport layer is greater than a content of hydrophobic material or alkaline material in the third electron transport layer.

In some embodiments, the protective layer comprises a salt layer, the protective layer comprises a first protective layer, a second protective layer and a third protective layer, an orthographic projection of the first protective layer on the first electrode at least partially overlaps with the orthographic projection of the red quantum dot light-emitting layer on the first electrode, an orthographic projection of the second protective layer on the first electrode at least partially overlaps with the orthographic projection of the green quantum dot light-emitting layer on the first electrode, an orthographic projection of the third protective layer on the first electrode at least partially overlaps with the orthographic projection of the blue quantum dot light-emitting layer on the first electrode, an amount of salt in the first protective layer is greater than an amount of salt in the second protective layer, and the amount of salt in the second protective layer is greater than an amount of salt in the third protective layer.

According to another aspect of the present disclosure, a display device is provided. The display device comprises the light-emitting device described in any of the previous embodiments.

According to yet another aspect of the present disclosure, a method of manufacturing a light-emitting device is provided. The method comprises: form a quantum dot light-emitting layer comprising organic acid groups; forming an electron transport layer on a side of the quantum dot light-emitting layer away from the first electrode; and forming a protective layer on a side of the quantum dot light-emitting layer away from the first electrode, wherein the protective layer blocks the organic acid group from contacting with the electron transport layer.

In some embodiments, forming the protective layer on the side of the quantum dot light-emitting layer away from the first electrode comprises: treating a surface of the quantum dot light-emitting layer with saturated steam containing an alkaline material, so that the alkaline material and excess organic acid groups on the surface of the quantum dot light-emitting layer have acid-base neutralization reaction to form a salt layer.

In some embodiments, forming the protective layer on the side of the quantum dot light-emitting layer away from the first electrode comprises: providing an anti-contact layer on the side of the quantum dot light-emitting layer away from the first electrode, wherein a material of the anti-contact layer comprises any one of hydrophobic material, silane coupling agent and epoxy resin; or providing an alkaline layer on the side of the quantum dot light-emitting layer away from the first electrode, wherein the alkaline layer and excess organic acid groups on the surface of the quantum dot light-emitting layer have acid-base neutralization reaction to form a salt layer.

In some embodiments, forming the electron transport layer on the side of the quantum dot light-emitting layer away from the first electrode and forming the protective layer on the side of the quantum dot light-emitting layer away from the first electrode comprises: doping an alkaline material into an electron transport material to form a mixed material, depositing the mixed material on the side of the quantum dot light-emitting layer away from the first electrode to form the electron transport layer, wherein the alkaline material in the mixed material and excess organic acid groups on the surface of the quantum dot light-emitting layer have acid-base neutralization reaction to form a salt layer; or depositing an electron transport material with a first ligand comprising a basic group on the side of the quantum dot light-emitting layer away from the first electrode to form the electron transport layer, wherein the basic group on the first ligand and excess organic acid groups on the surface of the quantum dot light-emitting layer have acid-base neutralization reaction to form a salt layer.

In some embodiments, the electron transport layer comprises a first electron transport layer, a second electron transport layer and a third electron transport layer, and the quantum dot light-emitting layer comprises a red quantum dot light-emitting layer, a green quantum dot light-emitting layer and a blue quantum dot light-emitting layer, and an orthographic projection of the first electron transport layer on the first electrode at least partially overlaps with an orthographic projection of the red quantum dot light-emitting layer on the first electrode, an orthographic projection of the second electron transport layer on the first electrode at least partially overlaps with an orthographic projection of the green quantum dot light-emitting layer on the first electrode, and an orthographic projection of the third electron transport layer on the first electrode at least partially overlaps with an orthographic projection of the blue quantum dot light-emitting layer on the first electrode, wherein doping an alkaline material into an electron transport material to form a mixed material, depositing the mixed material on the side of the quantum dot light-emitting layer away from the first electrode to form the electron transport layer comprises: doping the alkaline material and the electron transport material in a first molar ratio, a second molar ratio and a third molar ratio respectively to form a first mixed material, a second mixed material and a third mixed material, and depositing the first mixed material, the second mixed material and the third mixed material on the side of the quantum dot light-emitting layer away from the first electrode to form the first electron transport layer, the second electron transport layer and the third electron transport layer, wherein the first molar ratio is greater than the second molar ratio, and the second molar ratio is greater than the third molar ratio.

In some embodiments, forming the electron transport layer on the side of the quantum dot light-emitting layer away from the first electrode and forming the protective layer on the side of the quantum dot light-emitting layer away from the first electrode comprises: encapsulating an electron transport material with a surfactant, and depositing the electron transport material encapsulated with the surfactant on the side of the quantum dot light-emitting layer away from the first electrode to form the electron transport layer; or forming the surfactant on the side of the quantum dot light-emitting layer away from the first electrode, and forming the electron transport layer on the side of the surfactant away from the first electrode; wherein the protective layer comprises the surfactant.

In some embodiments, treating the intermediate layer or the quantum dot solution with the organic acid comprises: forming the intermediate layer on the first electrode, the intermediate layer comprising quantum dots, and treating the intermediate layer with saturated steam comprising the organic acid to form the quantum dot light-emitting layer on the first electrode; or forming the intermediate layer on the first electrode, the intermediate layer comprising quantum dots, applying an organic acid solution on a side of the intermediate layer away from the first electrode so that the intermediate layer is soaked by the organic acid solution, and removing the organic acid solution to form the quantum dot light-emitting layer on the first electrode; or preparing the quantum dot solution, the quantum dot comprising a quantum dot body and a second ligand coordinated on the quantum dot body, replacing at least some of the second ligands with the organic acid groups by a ligand exchange mode to form a treated quantum dot solution, and depositing the treated quantum dot solution on the first electrode to form the quantum dot light-emitting layer; or mixing the organic acid with the quantum dot solution, and depositing a mixed solution on the first electrode to form the quantum dot light-emitting layer.

### BRIEF DESCRIPTION OF THE DRAWINGS

In the following, exemplary embodiments of the present disclosure will be described in detail with reference to the accompanying drawings, in which:

FIG. 1 illustrates the change of current efficiency of a quantum dot light-emitting diode device with the increase of standing time;

FIG. 2 illustrates the change of current efficiency of a quantum dot light-emitting diode device with the increase of test times;

FIG. 3 illustrates the change of current efficiency of a quantum dot light-emitting diode device in the cases that the encapsulation glue contains acrylic acid and the encapsulation glue does not contain acrylic acid;

FIG. 4 illustrates the morphology of a quantum dot light-emitting diode device treated with acrylic acid and the morphology of a quantum dot light-emitting diode device not treated with acrylic acid;

FIG. 5 illustrates a schematic sectional view of a partial structure of a light-emitting device according to an embodiment of the present disclosure;

FIG. 6 illustrates a schematic sectional view of a partial structure of a light-emitting device according to an embodiment of the present disclosure;

FIG. 7 illustrates a general chemical formula of a first ligand of ZnO according to an embodiment of the present disclosure;

FIG. 8 illustrates a molecular structure of the group X in the general chemical formula of FIG. 7;

FIG. 9 illustrates another molecular structure of the group X in the general chemical formula of FIG. 7;

FIG. 10 illustrates yet another molecular structure of the group X in the general chemical formula of FIG. 7;

FIG. 11 illustrates yet another molecular structure of the group X in the general chemical formula of FIG. 7;

FIG. 12 illustrates a schematic sectional view of a partial structure of a light-emitting device according to an embodiment of the present disclosure;

FIG. 13 illustrates a schematic sectional view of a partial structure of a light-emitting device according to an embodiment of the present disclosure;

FIG. 14 illustrates a schematic sectional view of a partial structure of a light-emitting device according to an embodiment of the present disclosure;

FIG. 15 illustrates the brightness change of a red quantum dot light-emitting diode device with the increase of working time;

FIG. 16 illustrates the brightness change of a green quantum dot light-emitting diode device with the increase of working time;

FIG. 17 illustrates the brightness change of a blue quantum dot light-emitting diode device with the increase of working time;

FIG. 18 illustrates a schematic sectional view of a partial structure of a light-emitting device according to an embodiment of the present disclosure;

FIG. 19 illustrates a block diagram of a display device according to an embodiment of the present disclosure; and

FIG. 20 illustrates a flowchart of a method of manufacturing a light-emitting device according to an embodiment of the present disclosure.

It should be understood that the drawings are only schematic illustrations of exemplary embodiments of the present disclosure, which are not limitations of the present disclosure and need not be drawn to scale. In addition, in the drawings, the same or similar parts are indicated by the same or similar reference numbers.

### DETAILED DESCRIPTION OF THE DISCLOSURE

In the following, the technical solutions in the embodiments of the disclosure will be described clearly and completely in connection with the drawings in the embodiments of the disclosure. Obviously, the described embodiments are only part of the embodiments of the disclosure, and not all of the embodiments. Based on the embodiments in the present disclosure, all other embodiments obtained by those of ordinary skills in the art under the premise of not paying out creative work pertain to the protection scope of the disclosure.

Before formally describing the technical solutions of the embodiments of the present disclosure, the following explanations and definitions are given to terms used in the embodiments of the present disclosure, so as to help those skilled in the art to understand the technical solutions of the embodiments of the present disclosure more clearly.

In the present disclosure, the term “patterning process” or “patterning” includes but is not limited to processes such as film deposition, exposure and development. After “patterning process” or “patterning”, the “layer” contains at least one pattern.

In the present disclosure, terms such as “A is connected to B through a chemical bond” mean that A is bonded to B through a chemical bond. For example, A may be bonded to an atom on the surface of B or to a ligand of B through a chemical bond; similarly, B may be bonded to an atom on the surface of A or to a ligand of A through a chemical bond.

In the present disclosure, terms such as “A and B are in physical contact” mean that there is no chemical bond between A and B, and A and B are only in physical contact. Terms such as “A and B are in chemical contact” mean that A and B are bonded or connected to each other through a chemical bond.

Quantum dots (QD), as a new luminescent material, have the advantages of high light color purity, high luminescent quantum efficiency, adjustable luminescent color and long service life, and have become the research focus of new LED luminescent materials. Therefore, quantum dot light-emitting diode (QLED) with quantum dot material as light-emitting layer has become the main research direction of new display devices.

However, aging is an unavoidable problem for QLED devices. At a fixed current density, with the increase of standing time or test times, the brightness of QLED devices will increase first and then decrease, and the device efficiency will increase first and then decrease accordingly. The period of device efficiency increase is generally called positive aging.

For example, FIG. 1 illustrates the positive aging process of a QLED device. Curve E1 indicates that the standing time of the QLED device is one week, curve E2 indicates that the standing time of the QLED device is longer than the standing time of the QLED device of curve E1, and curve E3 indicates that the standing time of the QLED device is longer than the standing time of the QLED device of curve E2. It can be seen from FIG. 1 that, with the increase of standing time, the current efficiency of the QLED device is correspondingly improved continuously, which accords with the positive aging process of QLED devices.

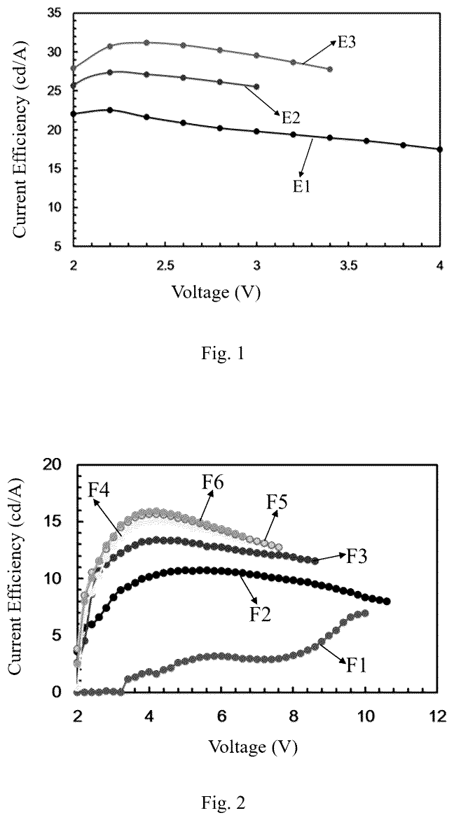

As another example, FIG. 2 illustrates the positive aging process of another QLED device. Curve F1 illustrates the results of the first test of current efficiency of the QLED device, curve F2 illustrates the results of the second test of current efficiency of the same QLED device, curve F3 illustrates the results of the third test of current efficiency of the same QLED device, curve F4 illustrates the results of the fourth test of current efficiency of the same QLED device, curve F5 illustrates the results of the fifth test of current efficiency of the same QLED device, and curve F6 illustrates the results of the sixth test of current efficiency of the same QLED device. It can be seen from FIG. 2 that, with the increase of test times, the current efficiency of the QLED device is correspondingly improved continuously, which accords with the positive aging process of QLED devices.

In conventional QLED devices, the positive aging process of QLED devices is usually accelerated by adding acrylic acid into the encapsulation glue, so that QLED devices can reach the maximum efficiency quickly.

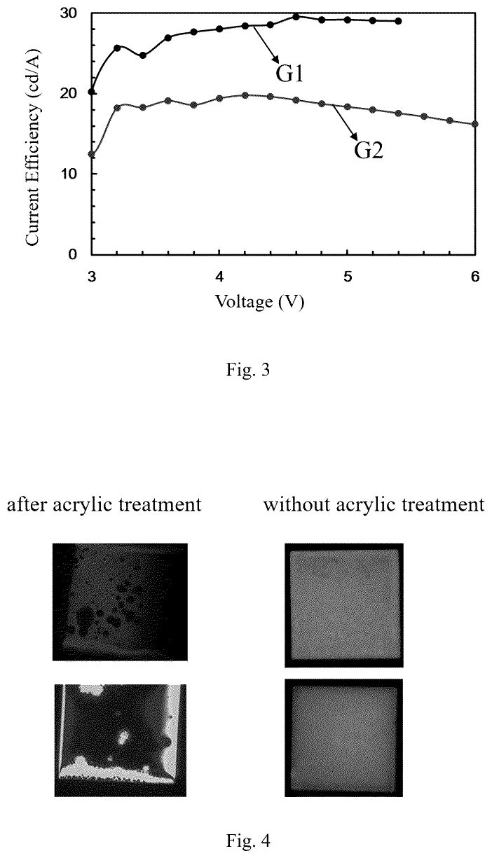

For example, FIG. 3 illustrates the current efficiency of two different QLED devices. Curve G1 indicates that the encapsulation glue of the QLED device contains acrylic acid, and curve G2 indicates that the encapsulation glue of the QLED device does not contain acrylic acid. Both QLED devices are in an upright structure, and the encapsulation glue is between the encapsulation glass and the substrate, and the quantum dot light-emitting layer is configured to emit red light. It can be seen from FIG. 3 that, by adding acrylic acid into the encapsulation glue, the current efficiency of the QLED device can be significantly improved, and the positive aging process of the QLED device can be accelerated.

Although the positive aging process of QLED devices can be accelerated by introducing acrylic acid into the encapsulation glue, this scheme will deteriorate the morphology of QLED devices, which is not conducive to the life of QLED devices. FIG. 4 illustrates the morphology of the two QLEDs in FIG. 3. It can be seen from FIG. 4 that the QLED's morphology is intact without acrylic treatment of the encapsulation glue, while the QLED's morphology is seriously deteriorated after acrylic treatment of the encapsulation glue. It is found that the acrylic acid in the encapsulation glue will damage the electron transport layer in QLED devices, which will lead to the deterioration of the morphology of the electron transport layer, and then lead to the deterioration of the morphology of QLED devices.

Therefore, when processing QLED devices, in the process of accelerating positive aging, some measures should be taken to avoid damage to the electron transport layer during processing, so as to avoid affecting the morphology of QLED devices.

To this end, some embodiments of the present disclosure provide a kind of light-emitting device, which comprises a first electrode, a quantum dot light-emitting layer on the first electrode and comprising organic acid groups, an electron transport layer on a side of the quantum dot light-emitting layer away from the first electrode, and a protective layer on the side of the quantum dot light-emitting layer away from the first electrode, and the protective layer blocks the organic acid groups of the quantum dot light-emitting layer from contacting with the electron transport layer.

The treatment of quantum dot light-emitting layer with organic acid is beneficial to accelerate the positive aging process of light-emitting devices, thus improving the current efficiency of light-emitting devices. However, if the organic acid contacts the electron transport layer, it will destroy the morphology of the electron transport layer, thus deteriorating the overall morphology of the light-emitting device. In embodiments of the present disclosure, by disposing the protective layer to block the organic acid groups on the quantum dot light-emitting layer from contacting with the electron transport layer, the morphology of the electron transport layer can be prevented from being destroyed. In this way, it can accelerate the positive aging process of the light-emitting device, while avoiding damage to the morphology of the light-emitting device and avoiding affecting the service life of the light-emitting device.

There are many forms of protective layer, for example, a hydrophobic layer can be arranged between the quantum dot light-emitting layer and the electron transport layer, and the hydrophobic layer acts as a protective layer; or a salt layer can be formed by applying an alkaline material above the quantum dot light-emitting layer and reacting the alkaline material with organic acid groups, and the salt layer acts as a protective layer; or by adding a hydrophobic material or an alkaline material into the electron transport layer, the alkaline material reacts with organic acid groups to form a salt layer, and the hydrophobic material or the salt layer acts as a protective layer; or the electron transport layer is encapsulated with a surfactant, the surfactant acts as a protective layer. Accordingly, the protective layer can be between the quantum dot light-emitting layer and the electron transport layer, or between the quantum dot light-emitting layer and the electron transport layer and inside the electron transport layer.

In the following, different arrangements of the protective layer in the light-emitting device are described in several embodiments.

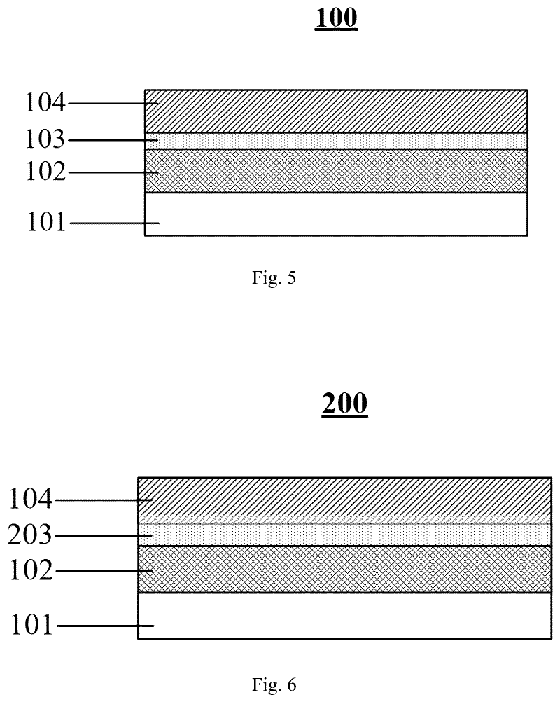

FIG. 5 illustrates a light-emitting device 100 according to an embodiment of the present disclosure, the light-emitting device 100 comprises a first electrode 101, a quantum dot light-emitting layer 102 comprising organic acid groups, a protective layer 103 on a side of the quantum dot light-emitting layer 102 away from the first electrode 101, and an electron transport layer 104 on a side of the protective layer 103 away from the first electrode 101. The protective layer 103 is between the quantum dot light-emitting layer 102 and the electron transport layer 104, and is configured to block the organic acid groups of the quantum dot light-emitting layer 102 from contacting with the electron transport layer 104.

During the preparation of the light-emitting device 100, an organic acid (such as unsaturated organic acid) may be used to treat the quantum dot solution or the quantum dot light-emitting layer, so that the formed quantum dot light-emitting layer 102 comprises organic acid groups. After organic acid treatment, a part of organic acid groups are connected to the surface of quantum dots through chemical bonds to passivate the defects on the surface of quantum dots, which plays a positive role and can promote the positive aging process of light-emitting device 100; another part of organic acid groups are not connected to the surface of quantum dots by chemical bonds, which have no passivation effect on the surface defects of quantum dots. These organic acid groups are called “excess organic acid groups”, so it is necessary to use alkaline materials to neutralize these excess organic acid groups to form a salt layer, or use hydrophobic materials to block these excess organic acid groups from contacting with the electron transport layer 104. The organic acid may be any suitable organic acid, including but not limited to acrylic acid, lewis acid, butyric acid, acetic acid, propionic acid, isobutyric acid, benzoic acid, methacrylic acid, 3-crotonic acid. These organic acids have carboxylic acids, delocalized π bonds or H ions, which can directly passivate the quantum dot light-emitting layer and its surface defects by coordination, inhibit surface exciton quenching, and increase exciton radiation recombination efficiency, thus significantly improving the positive aging effect of the light-emitting device 100. Organic acid groups can be detected in the quantum dot light-emitting layer 102 by infrared, mass spectrometry, nuclear magnetic resonance and other testing methods.

There are many ways to treat quantum dot solution or quantum dot light-emitting layer with organic acid, including but not limited to treating the quantum dot light-emitting layer with steam containing organic acid, soaking the quantum dot light-emitting layer with solvent containing organic acid, adding organic acid molecules to ligands of quantum dots, adding organic acid molecules to solvent of quantum dots. A quantum dot comprises a quantum dot body and a plurality of second ligands coordinated on the quantum dot body. After the quantum dot is treated in the above manner, a part of the second ligands on each quantum dot body are replaced by organic acid groups, organic acid groups are connected with the quantum dot body through coordination bonds. Therefore, the part of organic acid groups connected to the surface of the quantum dot by chemical bonds and used to passivate the surface defects of the quantum dot can be regarded as the replaced ligands on the quantum dot body. In some embodiments, the quantum dot light-emitting layer 102 comprises a plurality of quantum dots, at least some of the plurality of quantum dots comprise quantum dot bodies and second ligands coordinated on the quantum dot bodies, at least some of second ligands are the above-mentioned organic acid groups, and the general chemical formula of the second ligands is CₙH₂ₙ₋₁COOH (unsaturated fatty carboxylic acid) or C₆H₅—CₙH₂ₙ—COOH (aromatic carboxylic acid), and n is a positive integer greater than or equal to 1. In the preparation process, a part of the second ligands may be replaced by organic acid groups through ligand exchange, that is, organic acid groups may be used as the second ligands of the quantum dot body. In the general chemical formula CₙH2ₙ₋₁COOH or C₆H₅—CₙH₂ₙ—COOH, the number of C atoms may be less than or equal to 8, for example, so that the main chain structure is small, which is beneficial to enter the ligand gap of quantum dots, thereby passivating the quantum dot light-emitting layer 102 and its surface defects and inhibiting surface exciton quenching. These treatments of quantum dots by organic acids will be described in detail hereinafter, and will not be described herein.

In some embodiments, the protective layer 103 comprises a salt layer. When the protective layer 103 is a salt layer, it can be formed by applying an alkaline material on the surface of the quantum dot light-emitting layer 102 away from the first electrode 101 or treating the surface of the quantum dot light-emitting layer 102 away from the first electrode 101 with saturated vapor containing an alkaline material, when preparing the light-emitting device 100. Those organic acid groups that have been bonded to the surface of quantum dots through chemical bonds will not react with the alkaline material, while the excess organic acid groups in the quantum dot light-emitting layer 102 will react with the alkaline material to form a salt layer, that is, the protective layer 103. Illustratively, the protective layer 103 may be a carboxylate layer or a quaternary amine salt layer, depending on the types of organic acids and alkaline materials used. For example, the organic acid may be acrylic acid, lewis acid, butyric acid, acetic acid, propionic acid, isobutyric acid, benzoic acid, methacrylic acid, 3-butenoic acid, etc. as mentioned above, and the alkaline material may be organic base, quaternary amine base, lewis base, metal oxide, etc. If the organic acid is acrylic acid and the alkaline material is Mg(OH)₂, Al(OH)₃, MgO, Al₂O₃, etc., the salt generated by the neutralization reaction between the organic acid and the alkaline material may be magnesium acrylate or aluminum acrylate, etc. If the organic acid is acrylic acid and the alkaline material is quaternary amine base, the salt generated by the neutralization reaction between the organic acid and the alkaline material may be quaternary amine salts. The alkaline materials are usually weakly alkaline materials, and basically do not react with quantum dot materials and electron transport materials. Therefore, even if the alkaline materials are in contact with the quantum dot light-emitting layer 102 and the electron transport layer 104, the alkaline materials will not affect the performance of the quantum dot light-emitting layer 102 and the electron transport layer 104.

In some embodiments, the protective layer 103 may comprise unreacted alkaline materials in addition to the salt layer. In order to avoid the influence of organic acid groups on the quantum dot light-emitting layer 102 on the electron transport layer 104, an excessive amount of alkaline material is usually applied on the surface of the quantum dot light-emitting layer 102 to ensure that the excess organic acid groups are exhausted.

When applying an alkaline material on the surface of the quantum dot light-emitting layer 102 away from the first electrode 101 or treating the surface of the quantum dot light-emitting layer 102 away from the first electrode 101 with saturated vapor containing an alkaline material, the salt layer generated by the neutralization reaction between organic acid groups and the alkaline material is only in physical contact with the electron transport layer 104, and has no chemical bond with the electron transport layer 104.

In some alternative embodiments, the protective layer 103 is an anti-contact layer, and the material of the anti-contact layer is different from the material of the salt layer. The anti-contact layer prevents the organic acid groups in the quantum dot light-emitting layer 102 from contacting with the electron transport layer 104 through physical barrier. Illustratively, the materials of the anti-contact layer include but are not limited to, hydrophobic materials, silane coupling agents, epoxy resins, etc. The hydrophobic materials may be, for example, hexamethyldisilazane (HMDS).

FIG. 6 illustrates another light-emitting device 200 according to an embodiment of the present disclosure, which has basically the same configuration as the light-emitting device 100 except for the arrangement of the protective layer 203, and therefore the same reference numerals are used to refer to the same parts. Therefore, the detailed actions and functions of the parts in FIG. 6 with the same reference numbers as those in FIG. 5 can be referred to the description of FIG. 5, and will not be repeated here. For the sake of brevity, only the differences between the light-emitting device 200 and the light-emitting device 100 will be described below.

As shown in FIG. 6, the light-emitting device 200 comprises a first electrode 101, a quantum dot light-emitting layer 102 on the first electrode 101 and comprising organic acid groups, a protective layer 203 on a side of the quantum dot light-emitting layer 102 away from the first electrode 101, and an electron transport layer 104 on the side of the quantum dot light-emitting layer 102 away from the first electrode 101. Unlike the protective layer 103, the protective layer 203 is not only between the quantum dot light-emitting layer 102 and the electron transport layer 104, but also partially in the electron transport layer 104. Further, the protective layer 203 may be in a side of the electron transport layer 104 close to the quantum dot light-emitting layer 102, and the protective layer 203 is in contact with the quantum dot light-emitting layer 102.

The protective layer 203 may comprise a salt layer or an anti-contact layer.

When the protective layer 203 comprises a salt layer, it can be formed in the following two ways.

In one way, when preparing the electron transport layer 104, doping an alkaline material into an electron transport material (such as ZnO) to form a mixed material, and the mixed material is deposited on the side of the quantum dot light-emitting layer 102 away from the first electrode 101 to form the electron transport layer 104. At the same time, the alkaline material in the mixed material and the excess organic acid groups on the surface of the quantum dot light-emitting layer 102 have acid-base neutralization reaction to form a salt layer. As a protective layer 203, the salt layer is not only between the quantum dot light-emitting layer 102 and the electron transport layer 104, but also exists inside the electron transport layer 104. The term “doping” can be understood as mixing alkaline materials between ZnO particles. Because the alkaline material is mixed in the electron transport material by doping, in this case, the generated salt layer is only in physical contact with the electron transport layer 104, and is not connected by chemical bonds.

In another way, when preparing the electron transport layer 104, firstly, an electron transport material (such as ZnO) is prepared, which comprises a ZnO body and a first ligand coordinated on the ZnO body. The first ligand comprises a basic group, and the electron transport material is deposited on the side of the quantum dot light-emitting layer 102 away from the first electrode 101. In this case, the basic group on the first ligand and the excess organic acid groups on the surface of the quantum dot light-emitting layer 102 have acid-base neutralization reaction to form a salt. The protective layer 203 is not only between the quantum dot light-emitting layer 102 and the electron transport layer 104, but also exists inside the electron transport layer 104. The generated electron transport layer 104 comprises a ZnO body and a first coordination group (a corresponding structure after the basic group on the first ligand reacts with the organic acid group) coordinated on the ZnO body, and the salt layer (i.e., the protective layer 203) is connected with at least some of the first coordination groups through chemical bonds, that is, the salt layer is chemically connected with the electron transport layer 104.

In some embodiments, the electron transport layer 104 comprises a first surface close to the quantum dot light-emitting layer 102 and a second surface away from the quantum dot light-emitting layer 102, and the salt layer (i.e., the protective layer 203) is connected with the first coordination groups at the first surface through chemical bonds. This is because, in the preparation stage, the basic groups on the first ligands on the first surface of the electron transport layer 104 close to the quantum dot light-emitting layer 102 generally react with the excess organic acid groups on the quantum dot light-emitting layer 102 to form a salt layer, so the salt layer is generally connected with the first coordination groups on the first surface. However, the basic groups on the first ligands on the second surface of the electron transport layer 104 away from the quantum dot light-emitting layer 102 usually do not participate in the reaction, so the basic groups are still connected to the first ligands on the second surface.

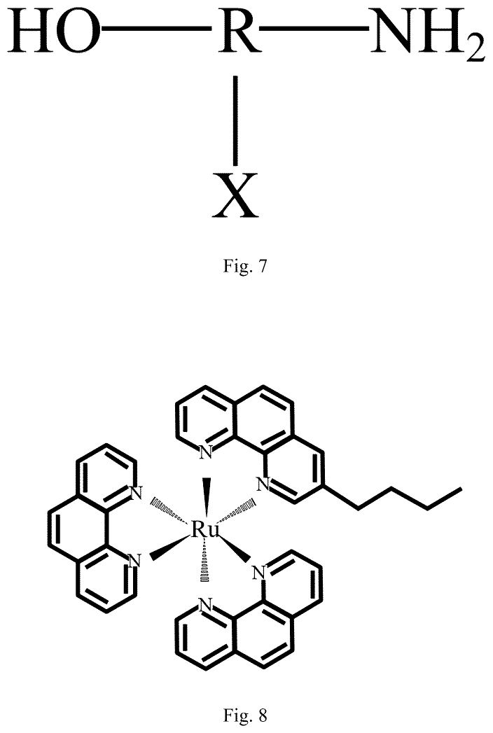

FIG. 7 illustrates the general chemical formula of the first ligand of ZnO, which is

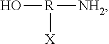

the first ligand may be, for example, an alcohol amine substance. In this general chemical formula, the group R represents an alkyl chain, and the group X may be the structure

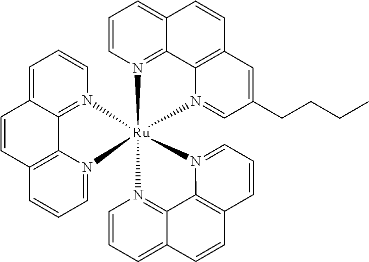

shown in FIG. 8, the structure

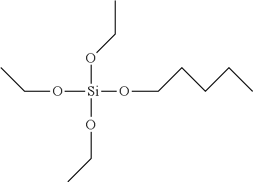 [SMILES: CCCCCO[Si](OCC)(OCC)OCC]

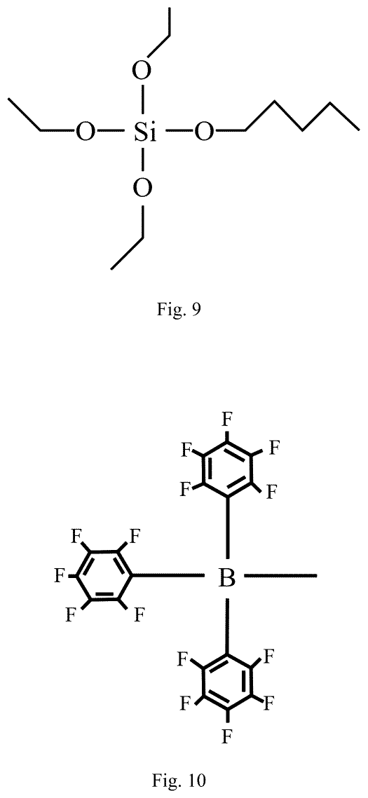

shown in FIG. 9, the structure

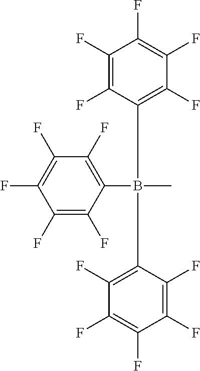

shown in FIG. 10 or the structure

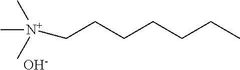

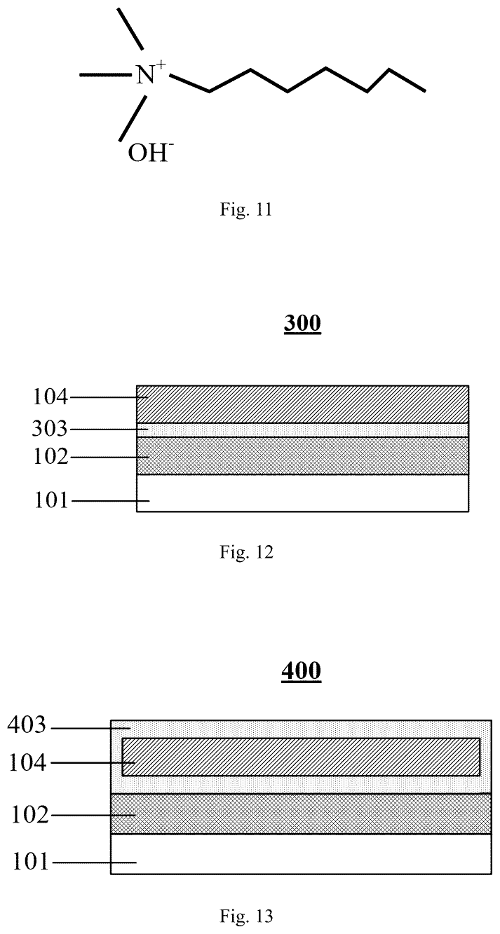

shown in FIG. 11.

When the protective layer 203 comprises an anti-contact layer, an anti-contact material may be doped into ZnO to form a mixed material when preparing the electron transport layer 104, and then deposit the mixed material on the side of the quantum dot light-emitting layer 102 away from the first electrode 101 to form the electron transport layer 104 and the anti-contact layer (i.e. the protective layer 203). In this case, the protective layer 203 is in physical contact with the electron transport layer 104. Alternatively, an anti-contact material may be introduced into the ligands of ZnO first, and then ZnO comprising the anti-contact material may be deposited on the side of the quantum dot light-emitting layer 102 away from the first electrode 101 to form the electron transport layer 104 and the anti-contact layer (i.e. the protective layer 203). In this case, the protective layer 203 is connected with the electron transport layer 104 through chemical bonds, and the two are in chemical contact. As a protective layer 203, the anti-contact layer exists not only between the quantum dot light-emitting layer 102 and the electron transport layer 104, but also inside the electron transport layer 104. The anti-contact layer can reduce or even avoid the contact between excess organic acid groups on the quantum dot light-emitting layer 102 and ZnO, and play a physical barrier role. The materials of the anti-contact layer include but are not limited to hydrophobic materials, silane coupling agents, epoxy resins. For example, the amino group or hydroxyl group in the anti-contact layer material may be connected to the surface site of ZnO, or May be connected to the ligand of ZnO.

FIG. 12 illustrates another light-emitting device 300 according to an embodiment of the present disclosure, which has basically the same configuration as the light-emitting device 100 except for the material of the protective layer 303, and therefore the same reference numerals are used to refer to the same parts. Therefore, detailed actions and functions of the parts in FIG. 12 with the same reference numbers as those in FIG. 5 can be referred to the description of FIG. 5, and will not be repeated here. For the sake of brevity, only the differences between the light-emitting device 300 and the light-emitting device 100 will be described below.

As shown in FIG. 12, the light-emitting device 300 comprises a first electrode 101, a quantum dot light-emitting layer 102 on the first electrode 101 and comprising organic acid groups, a protective layer 303 on a side of the quantum dot light-emitting layer 102 away from the first electrode 101, and an electron transport layer 104 on a side of the protective layer 303 away from the first electrode 101.

Unlike the protective layer 103 of the light-emitting device 100, the material of the protective layer 303 is not a salt layer or an anti-contact layer, but comprises a surfactant to protect the electron transport layer 104 from the influence of excess organic acid groups on the quantum dot light-emitting layer 102. In some embodiments, the surfactant encapsulates the electron transport layer 104. For example, the preparation process corresponding to these embodiments may be as follows: a surfactant layer is formed on the side of the quantum dot light-emitting layer 102 away from the first electrode 101, and the surfactant layer is used as the protective layer 303, and then the electron transport layer 104 is formed on the side of the protective layer 303 away from the first electrode 101. In alternative embodiments, the surfactant encapsulates the zinc oxide nanoparticles in the electron transport layer 104. For example, the preparation process corresponding to these embodiments may be as follows: firstly, a surfactant and zinc oxide nanoparticles are mixed to form a mixed material, and then the mixed material is deposited on the side of the quantum dot light-emitting layer 102 away from the first electrode 101 to form the protective layer 303 and the electron transport layer 104, the protective layer 303 comprising the surfactant. For example, the surfactant may physically encapsulate the electron transport layer 104 without chemical bonding with ZnO in the electron transport layer 104. The surfactant may form a vesicle-like structure to encapsulate ZnO in the electron transport layer 104. While protecting ZnO from the influence of organic acid groups, they can also increase the distance between ZnO particles, reduce electron injection and reduce conductivity, which is beneficial to charge balance.

In some embodiments, the general chemical formula of the surfactant may be expressed as A⁺B⁻, where A⁺ represents cation and B⁻ represents anion. For example, B⁻ may be selected from any one of halogen ions, hydroxide ions, PF₆⁻ and BF₄⁻, and the general chemical formula of A⁺ may be expressed as CₙH₂ₙ₊₁N(CₘH₂ₘ₊₁)₃ or CₙH₂ₙ₊₁N(CₘH₂ₘ₊₁)₂(CₘH₂ₘ₊₁)₂NCₙH₂ₙ₊₁, where n is any positive integer between 8 and 20, and m is any positive integer between 0 and 4. CₙH₂ₙ₊₁N(CₘH₂ₘ₊₁)₃ may be a cation of quaternary amine salt or a cation of quaternary amine base, which contains one N atom and is a single-center ion; CₙH₂ₙ₊₁N(CₘH₂ₘ₊₁)₂(CₘH₂ₘ₊₁)₂NCₙH₂ₙ₊₁ may be a cation of quaternary amine salt or a cation of quaternary amine base, which contains two N atoms and is a bicentric ion. Surfactant molecules are quaternary amine salts or quaternary amine bases molecules containing non-polar long-chain end.

FIG. 13 illustrates another light-emitting device 400 according to an embodiment of the present disclosure, which is a modification of the light-emitting device 300. In the light-emitting device 300, for example, the surfactant only encapsulates the electron transport layer 104 or zinc oxide nanoparticles from below the electron transport layer 104, while in the light-emitting device 400, the surfactant 403 encapsulates the electron transport layer 104 or zinc oxide nanoparticles from all sides. In this way, the electron transport layer 104 can be better protected from the influence of organic acid groups, the distance between ZnO particles can be further increased, and electron injection can be reduced, which is more conducive to charge balance.

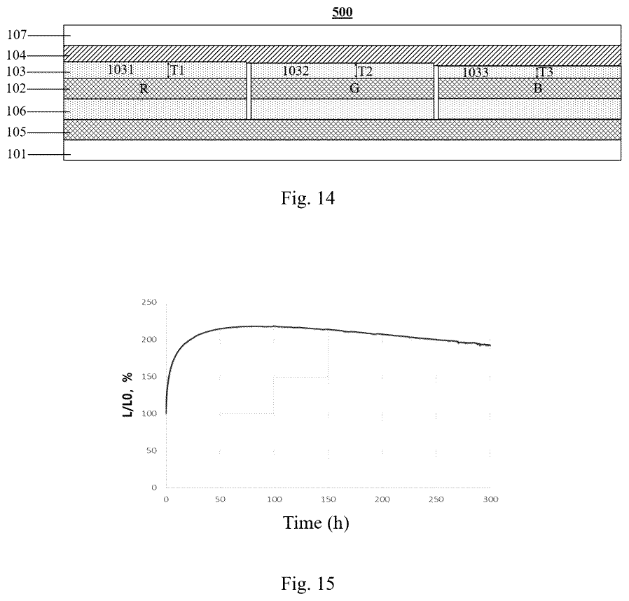

FIG. 14 illustrates a partial structural schematic diagram of a light-emitting device 500 according to an embodiment of the present disclosure. As shown in FIG. 14, in addition to the first electrode 101, the quantum dot light-emitting layer 102, the protective layer 103 and the electron transport layer 104, the light-emitting device 500 may also comprised a hole injection layer 105 between the first electrode 101 and the quantum dot light-emitting layer 102, a hole transport layer 106 between the hole injection layer 105 and the quantum dot light-emitting layer 102, and a second electrode 107 on the side of the electron transport layer 104 away from the first electrode 101. The first electrode 101 may be an anode, and the second electrode 107 may be a cathode. In this case, the light-emitting device 500 has an upright structure. It should be noted that although the protective layer shown in FIG. 14 is the protective layer 103, this is only an example, and the protective layer in the light-emitting device 500 may also be the protective layer 203 or the protective layer 303 described above.

For example, the material of the first electrode 101 includes but is not limited to ITO, FTO, conductive polymer, opaque metal electrodes such as Al, Ag. The material of the hole injection layer 105 includes but is not limited to PEDOT: PSS, MoOₓ, NiOₓ, VOₓ. The material of the hole transport layer 106 includes but is not limited to TFB, polyTPD, PVK. The material of the protective layer 103 includes but is not limited to a salt layer, an anti-contact layer, a surfactant. The material of the electron transport layer 104 includes but is not limited to ZnO, and the material of the second electrode 107 includes but is not limited to Al, Ag, IZO.

In some alternative embodiments, the light-emitting device 500 may also be an inverted structure, in which case, the light-emitting device 500 comprises a cathode, an electron transport layer, an (optional) protective layer, a quantum dot light-emitting layer, a hole transport layer, a hole injection layer, and an anode which are sequentially stacked. In the case of an inverted structure, the electron transport layer and/or the quantum dot light-emitting layer and/or the interface between them may be treated as described above. In some embodiments, the electron transport layer may be formed by sputtering process, and the electron transport layer formed by sputtering process is relatively dense and has strong solvent erosion resistance. In this case, the treatment of the electron transport layer may be omitted (for example, there is no need to introduce alkaline materials or hydrophobic materials into the electron transport layer), but the quantum dot light-emitting layer can be directly prepared on the electron transport layer, and the quantum dot light-emitting layer may be treated by organic acid.

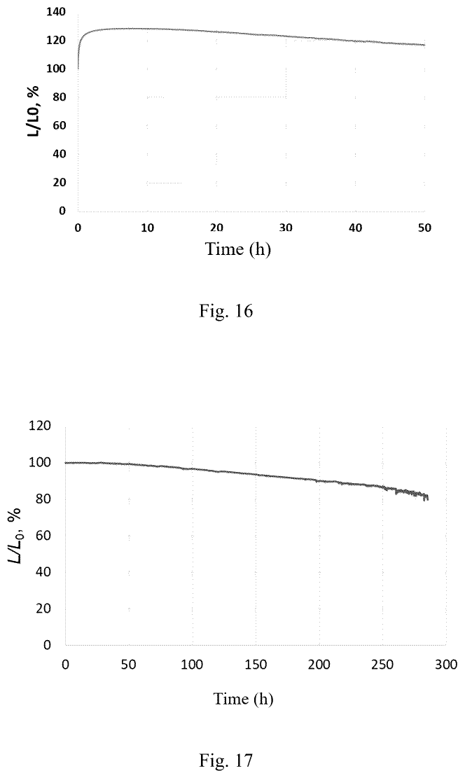

For light-emitting devices which emit red light (red light-emitting device for short), light-emitting devices which emit green light (green light-emitting device for short) and light-emitting devices which emit blue light (blue light-emitting device for short), their positive aging performance is generally different, which is mainly caused by quantum dot light-emitting layers with different colors. Generally speaking, the positive aging degree of red light-emitting devices is serious, with the increase of working time, its brightness is generally higher than the initial brightness by more than 30%, even reaching between 200% and 300%. The positive aging degree of green light-emitting devices is light, and its brightness will generally increase by 10%-50% with the increase of working time. However, blue light-emitting devices show less positive aging trend, with the increase of working time, their brightness generally does not increase, but decreases, that is, they enter a negative aging process. For example, FIG. 15 illustrates the brightness change of a red light-emitting device. It can be seen that with the increase of working time, the brightness of the red light-emitting device first rises and then falls (the current density remains unchanged), and the brightness can be increased to 200% or even more. FIG. 16 illustrates the brightness change of a green light-emitting device. It can be seen that with the increase of working time, the brightness of the green light-emitting device first rises and then falls (the current density remains unchanged), and the brightness can be increased to about 120%. FIG. 17 illustrates the brightness change of a blue light-emitting device. It can be seen that with the increase of working time, the brightness of the blue light-emitting device gradually decreases (current density remains unchanged), that is, the blue light-emitting device does not show a positive aging phenomenon with working time.

In order to avoid the obvious difference of positive aging phenomenon of quantum dot light-emitting layers with different colors, red, green and blue quantum dot light-emitting layers may be treated with different contents of organic acids.

Referring back to FIG. 14, the light-emitting device 500 comprises a red quantum dot light-emitting layer configured to emit red light R, a green quantum dot light-emitting layer configured to emit green light G, and a blue quantum dot light-emitting layer configured to emit blue light B. The red quantum dot light-emitting layer, the green quantum dot light-emitting layer, and the blue quantum dot light-emitting layer are separated from each other, and the red quantum dot light-emitting layer may correspond to a red subpixel, the green quantum dot light-emitting layer may correspond to a green subpixel, and the blue quantum dot light-emitting layer may correspond to a blue subpixel. The quantum dot light-emitting layer 102 comprises a plurality of quantum dots, each quantum dot comprises a quantum dot body and a plurality of second ligands coordinated on the quantum dot body, and a part of the second ligands in the plurality of second ligands are the aforementioned organic acid groups. Other second ligands other than organic acid groups in the second ligands may be ligands of various suitable materials. The molar ratio of organic acid groups to the plurality of second ligands on each quantum dot in the red quantum dot light-emitting layer is smaller than the molar ratio of organic acid groups to the plurality of second ligands on each quantum dot in the green quantum dot light-emitting layer, and the molar ratio of organic acid groups to the plurality of second ligands on each quantum dot in the green quantum dot light-emitting layer is smaller than the molar ratio of organic acid groups to the plurality of second ligands on each quantum dot in the blue quantum dot light-emitting layer.

As mentioned above, due to the quantum dot light-emitting layer, the positive aging degree of red light-emitting devices>green light-emitting devices>blue light-emitting devices. The effect of adding organic acids to the quantum dot light-emitting layer is to accelerate the positive aging. Because the positive aging effect of the red quantum dot light-emitting layer is the strongest, it needs to add the least amount of organic acids, while the positive aging effect of the blue quantum dot light-emitting layer is the weakest, so it needs to add the most amount of organic acids. Assuming that there are X moles of second ligands on each quantum dot body at first, after the quantum dot is treated with organic acid, about Y1 moles of the X moles of second ligands on the red quantum dot are replaced with organic acid groups, about Y2 moles of the X moles of second ligands on the green quantum dot are replaced with organic acid groups, and about Y3 moles of the X moles of second ligands on the blue quantum dot are replaced with organic acid groups, where Y1, Y2 and Y3 are all less than X, and Y1/X<Y2/X<Y3/X.

In some embodiments, in the red quantum dot light-emitting layer, the molar ratio of organic acid groups to the plurality of second ligands on each quantum dot is 0.1%-10%, for example, 0.1%, 5%, 10%. In the green quantum dot light-emitting layer, the molar ratio of organic acid groups to the plurality of second ligands on each quantum dot is 0.1%~20%, for example, 10%, 15%, 20%. In the blue quantum dot light-emitting layer, the molar ratio of organic acid groups to the plurality of second ligands on each quantum dot is 0.1%~60%, for example, 30%, 45%, 60%. It should be noted that although the molar ratios of 0.1%~10%, 0.1%~20% and 0.1%~60% overlap, this is only the possible molar ratio range of organic acid groups to the second ligands of their respective quantum dots. When the red quantum dot light-emitting layer, the green quantum dot light-emitting layer and the blue quantum dot light-emitting layer exist in a same light-emitting device, the respective molar ratios of organic acid groups to corresponding second ligands also need to satisfy that the molar ratio of organic acid groups to the plurality of second ligands on each quantum dot in the red quantum dot light-emitting layer is smaller than the molar ratio of organic acid groups to the plurality of second ligands on each quantum dot in the green quantum dot light-emitting layer, and the molar ratio of organic acid groups to the plurality of second ligands on each quantum dot in the green quantum dot light-emitting layer is smaller than the molar ratio of organic acid groups to the plurality of second ligands on each quantum dot in the blue quantum dot light-emitting layer.

It should be noted that the magnitude relationship or numerical range of the above molar ratio can be obtained by thermogravimetric analysis (TGA) and gas chromatography tandem mass spectrometry. For example, for the quantum dot light-emitting layer, various organics can be obtained from the quantum dot light-emitting layer comprising inorganic substances and various organics by TGA method, then the target organics can be obtained from the various organics by gas chromatography, and then the target atoms or target functional groups can be determined from the target organics by mass spectrometry or nuclear magnetic resonance, so that the molar ratio of organic acid groups to the second ligands can be obtained. Gas chromatography and mass spectrometry can usually be called gas chromatography tandem mass spectrometry.

In some embodiments, as shown in FIG. 14, the protective layer 103 is between the quantum dot light-emitting layer 102 and the electron transport layer 104, and the protective layer comprises a first protective layer 1031, a second protective layer 1032, and a third protective layer 1033. An orthographic projection of the first protective layer 1031 on the first electrode 101 at least partially overlaps with an orthographic projection of the red quantum dot light-emitting layer on the first electrode 101, an orthographic projection of the second protective layer 1032 on the first electrode 101 at least partially overlaps with an orthographic projection of the green quantum dot light-emitting layer on the first electrode 101, and an orthographic projection of the third protective layer 1033 on the first electrode 101 at least partially overlaps with an orthographic projection of the blue quantum dot light-emitting layer on the first electrode 101. A thickness T1 of the first protective layer 1031 is greater than a thickness T2 of the second protective layer 1032, and the thickness T2 of the second protective layer 1032 is greater than a thickness of the third protective layer 1033. The reason for this design is that the protective layer 103 not only protects ZnO from the corrosion of excess organic acid groups on the quantum dot light-emitting layer 102, but also plays an electron blocking role. Since the degree of electron surplus in red subpixel, green subpixel and blue subpixel is red subpixel>green subpixel>blue subpixel, the thickness T1 of the first protective layer 1031 corresponding to the red subpixel>the thickness T2 of the second protective layer 1032 corresponding to the green subpixel>the thickness T3 of the third protective layer 1033 corresponding to the blue subpixel, so that the electron blocking effect of the first protective layer 1031>the electron blocking effect of the second protective layer 1032>the electron blocking effect of the third protective layer 1033 can be realized. By controlling the thickness of the protective layer 103 at the interface between the quantum dot light-emitting layer 102 and the electron transport layer 104, the performance of the light-emitting device 500 can be unaffected, and even the electron injection can be reduced and the carrier balance can be increased.

In some embodiments, for the red subpixel, a protective layer 103 may be provided at the interface between the quantum dot light-emitting layer 102 and the electron transport layer 104, and an alkaline material and/or a hydrophobic material may be added in the electron transport layer 104 to further enhance the electron blocking effect of the protective layer at the red subpixel.

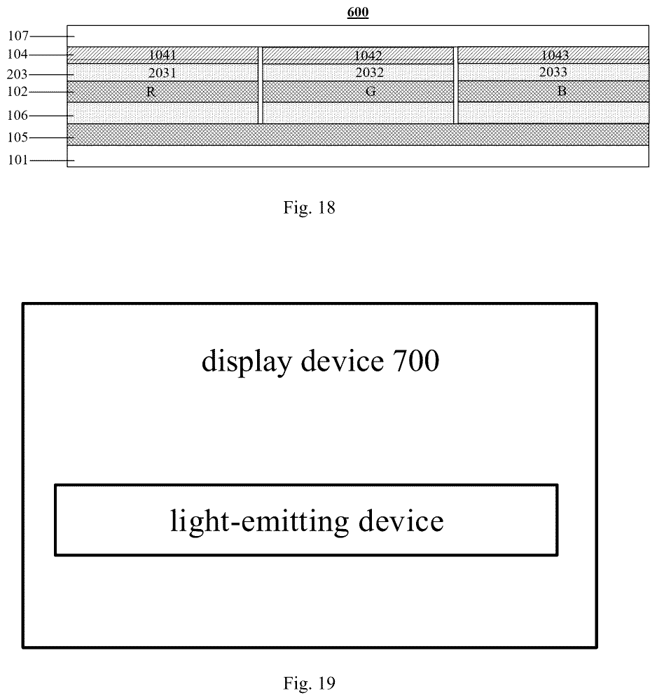

FIG. 18 illustrates a partial structural schematic diagram of a light-emitting device 600 according to another embodiment of the present disclosure. The light-emitting device 600 has basically the same configuration as the light-emitting device 500 except for the electron transport layer 104 and the protective layer 203, and therefore the same reference numerals are used to refer to the same parts. Therefore, the detailed actions and functions of the parts in FIG. 18 with the same reference numerals as those in FIG. 14 can be referred to the description of FIG. 14, and will not be repeated here. For the sake of brevity, only the differences between the light-emitting device 600 and the light-emitting device 500 will be described below.

As shown in FIG. 18, the light-emitting device 600 comprises a first electrode 101, a hole injection layer 105, a hole transport layer 106, a quantum dot light-emitting layer 102, a protective layer 203, an electron transport layer 104, and a second electrode 107. The protective layer 203 may be formed in the same way as the protective layer 203 of the light-emitting device 200 described in FIG. 6, and the electron transport layer 104 comprises a hydrophobic material or an alkaline material. The electron transport layer 104 comprises a first electron transport layer 1041, a second electron transport layer 1042 and a third electron transport layer 1043, and the protective layer 203 comprises a first protective layer 2031, a second protective layer 2032 and a third protective layer 2033. An orthographic projection of the first electron transport layer 1041 and the first protective layer 2031 on the first electrode 101 at least partially overlaps with an orthographic projection of the red quantum dot light-emitting layer on the first electrode 101, an orthographic projection of the second electron transport layer 1042 and the second protective layer 2032 on the first electrode 101 at least partially overlaps with an orthographic projection of the green quantum dot light-emitting layer on the first electrode 101, and an orthographic projection of the third electron transport layer 1043 and the third protective layer 2033 on the first electrode 101 at least partially overlaps with an orthographic projection of the blue quantum dot light-emitting layer on the first electrode 101.

In addition to controlling the thickness of the protective layer 103 at the interface between the quantum dot light-emitting layer 102 and the electron transport layer 104 as shown in FIG. 14, in the preparation stage of FIG. 18, the object of enhancing the electron blocking effect can also be achieved by controlling the addition amount of the alkaline material or the hydrophobic material in the electron transport layer 104. Specifically, the protective layer 203 is formed by making the content of hydrophobic material or alkaline material in the first electron transport layer 1041 corresponding to the red subpixel>the content of hydrophobic material or alkaline material in the second electron transport layer 1042 corresponding to the green subpixel>the content of hydrophobic material or alkaline material in the third electron transport layer 1043 corresponding to the blue subpixel. For the protective layer 203 formed in this way, the amount of hydrophobic material or salt in the first protective layer 2031 corresponding to the red subpixel>the amount of hydrophobic material or salt in the second protective layer 2032 corresponding to the green subpixel>the amount of hydrophobic material or salt in the third protective layer 2033 corresponding to the blue subpixel, so that the electron blocking effect of the first protective layer 2031>the electron blocking effect of the second protective layer 2032>the electron blocking effect of the third protective layer 2033 can also be achieved.

The contents of hydrophobic material or alkaline material in the first electron transport layer 1041, the second electron transport layer 1042, and the third electron transport layer 1043 can be obtained by an elemental analysis method, for example. The amounts of salt substances in the first protective layer 2031, the second protective layer 2032, and the third protective layer 2033 can be obtained by an elemental analysis method, for example.

It should be noted that the arrangement of the protective layer 103 and the electron transport layer 104 in the light-emitting device 500 and the arrangement of the protective layer 203 and the electron transport layer 104 in the light-emitting device 600 can be combined with each other without contradicting each other.

The quantum dots involved in the quantum dot light-emitting layer 102 in the light-emitting devices described in various embodiments of the present disclosure may be any suitable quantum dots, including but not limited to any of IIB-VIA quantum dots, IIIA-VA quantum dots, IVA-VIA quantum dots, core-shell quantum dots and ABX₃ perovskite quantum dots. In ABX₃ type perovskite quantum dots, A is one or more of CH₃NH³⁺ (methylamine), NH₂CH═NH₂ (formamidine) and Cs⁺, B is one or two of Pb²⁺ and Sn²⁺, X is one or more of Cl⁻, Br⁻ and I⁻, and ABX₃ type perovskite quantum dots comprise CH₃NH₃PbBr₃, CH₃NH₃PbCl₃, CH₃NH₃PbI₃, CsPbBr₃, CsPbCl₃ and CsPbI₃.

Exemplary, the IIB-VIA quantum dots are selected from one or more binary compounds such as CdSe, CdTe, ZnS, ZnSe, ZnTe, ZnO, HgS, HgSe, HgTe, MgSe and MgS; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS or mixtures thereof; and quaternary compounds such as HgZnTeS, CdZnSeS, CdZnSeTe, CdZnSTe, CdHgSeS, CdHgSeTe, CdHgSTe, HgZnSeS, HgZnSeTe, HgZnSTe, or mixtures thereof, but not limited thereto.

Group IIIA-VA quantum dots are selected from binary compounds such as GaN, GaP, GaAs, GaSb, AlN, AlP, AlAs, AlSb, InN, InP, InAs, InSb, or mixtures thereof; ternary compounds such as GaNP, GaNAs, GaNSb, GaPAs, GaPSb, AlNP, AlNAs, AlNSb, AlPAs, AlPSb, InNP, InNAs, InNSb, InPAs, InPSb, or mixtures thereof; and quaternary compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPASb, or mixtures thereof, but not limited thereto.

IVA-VIA quantum dots are selected from binary compounds such as SnS, SnSe, SnTe, PbS, PbSe, PbTe, or mixtures thereof; ternary compounds such as SnSeS, SnSeTe, SnSTe, PbSeS, PbSeTe, PbSTe, SnPbSe, SnPbSe, SnPbTe, or mixtures thereof; and quaternary compounds such as SnPbSSe, SnPbSeTe, SnPbSTe, or mixtures thereof, but not limited thereto. IVA-VIA quantum dots are, for example, selected from elementary substance (unitary) semiconductors such as Si, Ge, or mixtures thereof; and binary semiconductor compounds such as SiC, SiGe, and mixtures thereof, but not limited thereto.

Quantum dots with core-shell structure mean that one material is the core material and the other is the shell material. For example, the quantum dot is CdS/ZnS, which means that the core material of the quantum dot is CdS and the shell material is ZnS.

In other embodiments, quantum dots may be other nano-scale materials, such as nanorods, nanosheets. Components of other nano-scale materials may comprise at least one of CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaN, ZnTe. Si, Ge and C.

For example, the quantum dots may comprise cadmium free quantum dots. Cadmium-free quantum dots are quantum dots that do not comprise cadmium (Cd). Cadmium (Cd) can cause serious environmental/health problems, so non-Cd-based quantum dots can be effectively used.

FIG. 19 illustrates a block diagram of a display device 700 according to an embodiment of the present disclosure. The display device 700 comprises a plurality of light-emitting devices, and in some embodiments, each light-emitting device comprises a quantum dot light-emitting layer that emits light of a single color. For example, some light-emitting devices comprise red quantum dot light-emitting layers and are configured to emit red light; some light-emitting devices comprise green quantum dot light-emitting layers and are configured to emit green light; some light-emitting devices comprise blue quantum dot light-emitting layers and are configured to emit blue light. In some alternative embodiments, each light-emitting device comprises quantum dot light-emitting layers that emit light of different colors, for example, each light-emitting device comprises quantum dot light-emitting layers that emit light of three different colors of red, green and blue. Of course, the display device 700 also comprises other components not shown, for example, it may comprise a driving circuit for providing an electrical signal to the light-emitting device to drive the light-emitting device to emit light. The display device 700 may also comprise a circuit board and/or an integrated circuit (IC).

The display device 700 may be a mobile phone, a tablet computer, a television, a display, a notebook computer, a digital photo frame, a navigator and other products or components that display based on quantum dots.

The display device 700 may have basically the same technical effect as the light-emitting device described in the previous embodiment, so for the sake of brevity, the description will not be repeated here.

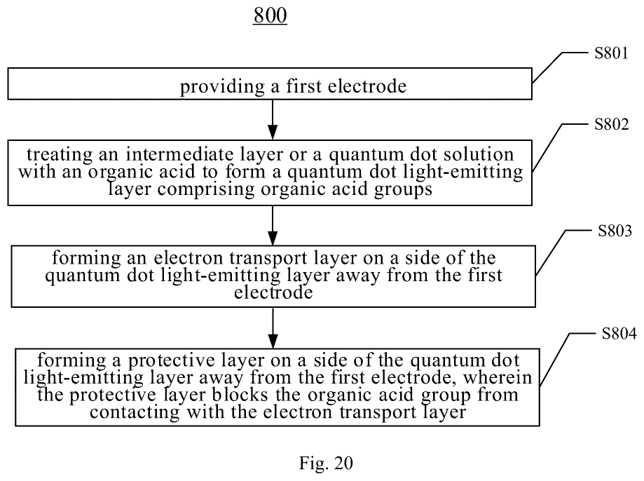

FIG. 20 illustrates a flowchart of a method 800 of manufacturing a light-emitting device. As shown in FIG. 20, the method 800 comprises the following steps:

S801: providing a first electrode.

S802: treating an intermediate layer or a quantum dot solution with an organic acid to form a quantum dot light-emitting layer comprising organic acid groups.

The “intermediate layer” here refers to the film layer in a certain state before the final formation of the quantum dot light-emitting layer 102, which is in the form of a “layer”. “Quantum dot solution” refers to a solution comprising quantum dots, which is used to form a quantum dot light-emitting layer.

S803: forming an electron transport layer on a side of the quantum dot light-emitting layer away from the first electrode.

S804: forming a protective layer on a side of the quantum dot light-emitting layer away from the first electrode, wherein the protective layer blocks the organic acid group from contacting with the electron transport layer.

In the method 800, by forming a protective layer to prevent the organic acid groups on the quantum dot light-emitting layer from contacting with the electron transport layer, the morphology of the electron transport layer can be prevented from being destroyed. In this way, it can accelerate the positive aging process of the light-emitting device, while avoiding damage to the morphology of the light-emitting device and avoiding affecting the service life of the light-emitting device.

In the following, different manufacturing methods of light-emitting devices will be described in more detail with several embodiments or examples.

### Method 1

First, a first electrode 101 is deposited on a substrate. The material of the substrate may be, for example, glass or flexible PET. The material of the first electrode 101 may be, for example, transparent ITO, FTO, conductive polymer, or opaque metal electrodes such as Al and Ag.

Then, a hole injection layer 105 is deposited on the first electrode 101 by spin coating or magnetron sputtering. The material of the hole injection layer 105 includes but is not limited to PEDOT: PSS, MoOₓ, NiOₓ, WOₓ, VOₓ. For example, the thickness of the hole injection layer 105 may be between 20 and 100 nm.

Then, a hole transport layer 106 is deposited on a side of the hole injection layer 105 away from the first electrode 101. The material of the hole transport layer 106 includes but is not limited to TFB, polyTPD, PVK.

Then, a red quantum dot intermediate layer is deposited on a side of the hole transport layer 106 away from the first electrode 101, and then the red quantum dot intermediate layer is treated with saturated steam comprising organic acid for a first duration, the first duration may be, for example, 0-minutes. In saturated steam atmosphere comprising organic acids, the proportion of organic acids may be 1%~100%. The organic acid may be unsaturated organic acid, including but not limited to acrylic acid, lewis acid, butyric acid, acetic acid, propionic acid, isobutyric acid, benzoic acid, methacrylic acid, 3-crotonic acid. After organic acid treatment, organic acid groups can be detected in the red quantum dot light-emitting layer by infrared, mass spectrometry, nuclear magnetic resonance and other testing methods. For example, the red quantum dot intermediate layer may be cross-linked and developed to form a pattern, and then the patterned layer can be treated with saturated steam comprising organic acid. Alternatively, the red quantum dot intermediate layer may be treated with saturated steam comprising organic acid first, and then cross-linked and developed to form a pattern. When the red quantum dot light-emitting layer is patterned, the hole transport layer 106 below is patterned at the same time, so only the patterned hole transport layer 106 is left at the red subpixel. In some embodiments, the thickness of the red quantum dot light-emitting layer is 20-50 nm.

Then, a hole transport layer is deposited.

Then, the green quantum dot intermediate layer is deposited, and the green quantum dot intermediate layer is treated by saturated steam comprising organic acid for a second duration, the second duration may be, for example, 0-30 minutes. By patterning the green quantum dot intermediate layer and the hole transport layer, a stacked hole transport layer pattern and a green quantum dot light-emitting layer can be formed in the green subpixel. In some embodiments, the thickness of the green quantum dot light-emitting layer is 20-50 nm.

Then, a hole transport layer is deposited.

Then, the blue quantum dot intermediate layer is deposited, and the blue quantum dot intermediate layer is treated by saturated steam comprising organic acid for a third duration, the third duration may be, for example, 0-60 minutes. By patterning the blue quantum dot intermediate layer and the hole transport layer, a stacked hole transport layer pattern and a blue quantum dot light-emitting layer can be formed in the blue subpixel. In some embodiments, the thickness of the blue quantum dot light-emitting layer is 20-50 nm.

After organic acid treatment, a part of organic acid groups are connected to the surface of red, green and blue quantum dots through chemical bonds, so as to passivate the defects on the surface of quantum dots, and this part of organic acid groups play a positive role and can promote the positive aging process of light-emitting devices; another part of organic acid groups are not connected to the surface of red, green and blue quantum dots by chemical bonds, which have no passivation effect on the surface defects of quantum dots, these organic acid groups are called “excess organic acid groups”. For example, before the organic acid treatment, a quantum dot comprises a quantum dot body and a plurality of second ligands coordinated on the quantum dot body. After the organic acid treatment in the first method, a part of the second ligands on each quantum dot body are replaced by organic acid groups, the organic acid groups are connected with the quantum dot body through coordination bonds. Therefore, the part of organic acid groups connected to the surface of the quantum dot by chemical bonds and used to passivate the surface defects of the quantum dot can be regarded as the replaced ligands on the quantum dot body.

Then, the surface of the red, green and blue quantum dot light-emitting layer 102 away from the first electrode 101 is treated with saturated steam comprising an alkaline material, so that the alkaline material and excess organic acid groups on the surface of the red, green and blue quantum dot light-emitting layer 102 undergo acid-base neutralization reaction, thereby forming a salt layer, that is, a protective layer 103, on the side of the red, green and blue quantum dot light-emitting layer 102 away from the first electrode 101. Those organic acid groups that have been bonded to the surface of quantum dots through chemical bonds will not react with the alkaline material, while the excess organic acid groups in the quantum dot light-emitting layer 102 will react with the alkaline material to form a salt layer, that is, the protective layer 103. Illustratively, the protective layer 103 may be a carboxylate layer or a quaternary amine salt layer, depending on the types of organic acids and alkaline materials used. For example, the organic acid may be acrylic acid, lewis acid, butyric acid, acetic acid, propionic acid, isobutyric acid, benzoic acid, methacrylic acid, 3-butenoic acid, etc. as mentioned above, and the alkaline material may be organic base, quaternary amine base, lewis base, metal oxide, etc. If the organic acid is acrylic acid and the alkaline material is Mg(OH)₂, Al(OH)₃, MgO, Al₂O₃, etc., the salt generated by the neutralization reaction between the organic acid and the alkaline material may be magnesium acrylate or aluminum acrylate, etc. If the organic acid is acrylic acid and the alkaline material is quaternary amine base, the salt generated by the neutralization reaction between the organic acid and the alkaline material may be quaternary amine salts. The alkaline materials are usually weakly alkaline materials, and basically do not react with quantum dot materials and electron transport materials. Therefore, even if the alkaline materials are in contact with the quantum dot light-emitting layer 102 and the electron transport layer 104, the alkaline materials will not affect the performance of the quantum dot light-emitting layer 102 and the electron transport layer 104.

Then, an electron transport material is deposited on a side of the protective layer 103 away from the first electrode 101 to form an electron transport layer 104. The electron transport material includes but is not limited to ZnO. The electron transport material can be deposited in different subpixels by inkjet printing, lithography and other methods.

Finally, a second electrode 107 is deposited on a side of the electron transport layer 104 away from the first electrode 101. The material of the second electrode 107 includes but is not limited to Al, Ag, IZO. The thickness of the second electrode 107 may be 10~100 nm.

In the first method, the content of organic acids on the surface of quantum dot light-emitting layers with different colors will be different with different treatment time. For example, if the first duration<the second duration<the third duration, the molar ratio of organic acid groups on each quantum dot in the red quantum dot light-emitting layer to the initial second ligands (without organic acid treatment)<the molar ratio of organic acid groups on each quantum dot in the green quantum dot light-emitting layer to the initial second ligands (without organic acid treatment)<the molar ratio of organic acid groups on each quantum dot in the blue quantum dot light-emitting layer to the initial second ligands (without organic acid treatment). As mentioned above, due to the quantum dot light-emitting layer, the positive aging degree of red light-emitting devices>the positive aging degree of green light-emitting devices>the positive aging degree of blue light-emitting devices. The effect of adding organic acids to the quantum dot light-emitting layer is to accelerate the positive aging, since the positive aging effect of the red quantum dot light-emitting layer is the strongest, it needs to add the least amount of organic acids, while the positive aging effect of the blue quantum dot light-emitting layer is the weakest, so it needs to add the most amount of organic acids.

In short, in the first method, the quantum dot intermediate layer is treated with saturated steam comprising organic acids to connect the organic acids with the quantum dots through chemical bonds, and the surface of the formed quantum dot light-emitting layer is treated with saturated steam comprising alkaline materials, and the alkaline materials react with excess organic acid groups on the quantum dot light-emitting layer 102 to form a protective layer 103 between the quantum dot light-emitting layer 102 and the electron transport layer 104.

### Method 2:

Compared with the first method, other processes remain unchanged, and the only difference is that when preparing the red, green and blue quantum dot light-emitting layers, the organic acids are mixed with the corresponding quantum dot solution instead of treating the quantum dot intermediate layer with saturated steam comprising the organic acids, and then the mixed solutions are deposited on the first electrode 101 to form the red, green and blue quantum dot light-emitting layers respectively. After adding organic acids into the quantum dot solution, some defects on the surface of the quantum dot or the atoms on the surface will be connected with the organic acid molecules through chemical bonds.

Before being treated with organic acid, a quantum dot comprises a quantum dot body and a plurality of second ligands coordinated on the quantum dot body. After being treated with organic acid in the second method, a part of the second ligands on each quantum dot body are replaced by organic acid groups, the organic acid groups are connected with the quantum dot bodies through coordination bonds. Therefore, the part of organic acid groups connected to the surface of quantum dots by chemical bonds and used to passivate surface defects of quantum dots can be regarded as the replaced ligands on the quantum dot body.

In some embodiments, the content of organic acids is different in different quantum dot solutions. For example, in the red quantum dot solution, the molar ratio of the organic acid to the second ligand may be 0.1-10%, such as 0.1%, 5%, 10%. In the green quantum dot solution, the molar ratio of organic acid to the second ligand may be 0.1~20%, such as 10%, 15%, 20%. In the blue quantum dot solution, the molar ratio of organic acid to the second ligand may be 0.1~60%, such as 30%, 45%, 60%.

The solvent for the organic acids may be the same as the solvent for quantum dot, organic acids generally have strong solubility and can be dissolved in both polar and non-polar solvents.

In short, in the second method, organic acid molecules are added to the quantum dot solution to connect the organic acid with the quantum dot through chemical bonds, and the surface of the formed quantum dot light-emitting layer is treated by saturated steam comprising alkaline materials, and the alkaline materials react with the excess organic acid groups on the quantum dot light-emitting layer 102 to form a protective layer 103 between the quantum dot light-emitting layer 102 and the electron transport layer 104.

### Method 3

Compared with the first method, other processes remain unchanged, and the only difference is that when preparing the red, green and blue quantum dot light-emitting layer, a quantum dot intermediate layer with corresponding color is first formed on the first electrode 101, and then an organic acid solution is applied to the side of the intermediate layer away from the first electrode 101, so that the quantum dot intermediate layer is soaked by the organic acid solution, and then the organic acid solution is removed, thereby forming the red, green and blue quantum dot light-emitting layer comprising organic acid groups on the first electrode 101. For example, first, a quantum dot intermediate layer with a corresponding color is formed on the first electrode 101, then an organic acid solution, such as an ethanol solution of acrylic acid, is dripped over the quantum dot intermediate layer, so that the quantum dot intermediate layer is soaked by the ethanol solution of acrylic acid, and then the ethanol solution of acrylic acid is spun off by spin coating, thereby forming a red, green and blue quantum dot light-emitting layer comprising organic acid groups on the first electrode 101.

Before being treated with organic acid, a quantum dot comprises a quantum dot body and a plurality of second ligands coordinated on the quantum dot body. After being treated with organic acid in the third method, a part of the second ligands on each quantum dot body are replaced by organic acid groups, the organic acid groups are connected with the quantum dot bodies through coordination bonds. Therefore, the part of organic acid groups connected to the surface of quantum dots by chemical bonds and used to passivate surface defects of quantum dots can be regarded as the replaced ligands on the quantum dot body.

In short, in the third method, the quantum dot intermediate layer is soaked with the organic acid to connect the organic acid with the quantum dot through chemical bonds, and the surface of the formed quantum dot light-emitting layer is treated by saturated steam comprising alkaline materials, and the alkaline materials react with the excess organic acid groups on the quantum dot light-emitting layer 102 to form a protective layer 103 between the quantum dot light-emitting layer 102 and the electron transport layer 104.

### Method 4

Compared with the first method, other processes remain unchanged, and the only difference is that when preparing the red, green and blue quantum dot light-emitting layer, part of the ligands of the quantum dots are replaced by organic acids by ligand exchange. Specifically, firstly, a quantum dot solution is prepared, and a quantum dot comprises a quantum dot body and second ligands coordinated on the quantum dot body; at least some of the second ligands are replaced by organic acid groups through ligand exchange to form a treated quantum dot solution; and then, the treated quantum dot solution is deposited on the first electrode 101 to form red, green and blue quantum dot light-emitting layers respectively.

In one example, the ligand exchange method may be as follows: firstly, ethanol is added to the nonpolar solution (such as octane) of quantum dots to precipitate the quantum dots, then the quantum dot powder is put into the ethanol solution comprising photosensitive ligands and unsaturated organic acids for ligand exchange, then washed with ethanol for 1-3 times, and finally, the above solution is redissolved in the amphoteric solution PGMEA.

The general chemical formula of the second ligands of the quantum dot may be CₙH₂ₙ₋₁COOH (unsaturated fatty carboxylic acid) or C₆H₅—CₙH₂ₙ—COOH (aromatic carboxylic acid), and n is a positive integer greater than or equal to 1. The material of the second ligand may be butyric acid, acetic acid, propionic acid, isobutyric acid, acrylic acid, benzoic acid, methacrylic acid, 3-crotonic acid, etc. In the general chemical formula CₙH₂ₙ₋₁COOH or C₆H₅—CₙH₂ₙ—COOH, the number of C atoms may be less than or equal to 8, for example, so that the main chain structure is small, which is beneficial to enter the ligand gap of quantum dots, thereby passivating the quantum dot light-emitting layer and its surface defects and inhibiting surface exciton quenching.

Before being treated with organic acid, a quantum dot comprises a quantum dot body and a plurality of second ligands coordinated on the quantum dot body. After being treated with organic acid in the fourth method, a part of the second ligands on each quantum dot body are replaced by organic acid groups, the organic acid groups are connected with the quantum dot bodies through coordination bonds. Therefore, the part of organic acid groups connected to the surface of quantum dots by chemical bonds and used to passivate surface defects of quantum dots can be regarded as the replaced ligands on the quantum dot body.

In short, in the fourth method, organic acid molecules are introduced into the quantum dot ligands to connect the organic acid with the quantum dot through chemical bonds, and the surface of the formed quantum dot light-emitting layer is treated by saturated steam comprising alkaline materials, and the alkaline materials react with the excess organic acid groups on the quantum dot light-emitting layer 102 to form a protective layer 103 between the quantum dot light-emitting layer 102 and the electron transport layer 104.

Methods 1, 2, 3 and 4 treat the intermediate layer or solution of quantum dots by different means, so that organic acid groups are connected to the surface of quantum dots through chemical bonds. In the quantum dot light-emitting layer obtained after treatment by methods 1, 2, 3 and 4, part of the second ligands on each quantum dot body are replaced by organic acid groups, so the chemical structure of the quantum dot light-emitting layer obtained after treatment by methods 1, 2, 3 and 4 can be basically regarded as the same.

### Method 5

In the fifth method, any one of the above-mentioned methods 1, 2, 3 and 4 can be used to treat the quantum dot light-emitting layer, and the preparation method of the electron transport layer 104 is different from the first method. In the fifth method, when preparing the electron transport layer 104, an alkaline material is first doped in the electron transport material ZnO to form a mixed material, and then the mixed material is deposited on the side of the quantum dot light-emitting layer 102 away from the first electrode 101, and the alkaline material in the mixed material reacts with the excess organic acid groups on the surface of the quantum dot light-emitting layer 102 to form a salt layer, i.e. the protective layer 203. In some embodiments, the molar ratio of alkaline material to ZnO in the mixed material is 0.1%~60%, such as 0.1%, 30%, 60%. The alkaline material may be, for example, an organic base or a lewis base. The preparation method and process of other film layers are the same as the first method.

In some embodiments, the electron transport layer 104 comprises a first electron transport layer 1041, a second electron transport layer 1042, and a third electron transport layer 1043, the quantum dot light-emitting layer comprises a red quantum dot light-emitting layer, a green quantum dot light-emitting layer, and a blue quantum dot light-emitting layer, and an orthographic projection of the first electron transport layer 1041 on the first electrode 101 at least partially overlaps with an orthographic projection of the red quantum dot light-emitting layer on the first electrode 101, an orthographic projection of the second electron transport layer 1042 on the first electrode 101 at least partially overlaps with an orthographic projection of the green quantum dot light-emitting layer on the first electrode 101, and an orthographic projection of the third electron transport layer 1043 on the first electrode 101 at least partially overlaps with an orthographic projection of the blue quantum dot light-emitting layer on the first electrode 101. Doping the alkaline material in the electron transport material to form the mixed material, and depositing the mixed material on the side of the quantum dot light-emitting layer away from the first electrode to form the electron transport layer, comprises: doping the alkaline material and the electron transport material ZnO in a first molar ratio, a second molar ratio, and a third molar ratio to form a first mixed material, a second mixed material and a third mixed material respectively, and depositing the first mixed material, the second mixed material and the third mixed material on the side of the quantum dot light-emitting layer 102 away from the first electrode 101 to form a first electron transport layer 1041, a second electron transport layer 1042 and a third electron transport layer 1043, wherein the first molar ratio is greater than the second molar ratio, and the second molar ratio is greater than the third molar ratio. Illustratively, the content of alkaline material in the first electron transport layer 1041 is greater than the content of alkaline material in the second electron transport layer 1042, and the content of alkaline material in the second electron transport layer 1042 is greater than the content of alkaline material in the third electron transport layer 1043.

For the protective layer 203 formed in this way, the amount of salt in the first protective layer 2031 corresponding to the red subpixel>the amount of salt in the second protective layer 2032 corresponding to the green subpixel>the amount of salt in the third protective layer 2033 corresponding to the blue subpixel. In this way, it can be achieved that the electron blocking effect of the first protective layer 2031>the electron blocking effect of the second protective layer 2032>the electron blocking effect of the third protective layer 2033, which is conducive to enhancing the electron blocking effect at the red subpixel.

The protective layer 203 formed by the fifth method is not only between the quantum dot light-emitting layer 102 and the electron transport layer 104, but also inside the electron transport layer 104. The protective layer 203 is in physical contact with the electron transport layer 104 because the alkaline material is doped in ZnO without being connected to ZnO by chemical bonds.

### Method 6

In the sixth method, any one of the above-mentioned methods 1, 2, 3 and 4 can be used to treat the quantum dot light-emitting layer, and the formation method of the protective layer 103 is different from the first method. In the sixth method, an anti-contact layer is provided on the side of the quantum dot light-emitting layer 102 away from the first electrode 101, and the material of the anti-contact layer may be any one of hydrophobic material HMDS, silane coupling agent and epoxy resin, and the anti-contact layer acts as a protective layer 103. Alternatively, an alkaline layer is provided on the side of the quantum dot light-emitting layer 102 away from the first electrode 101, and the alkaline layer reacts with excess organic acid groups on the surface of the quantum dot light-emitting layer 102 to form a salt layer, and the salt layer acts as the protective layer 103. The protective layer 103 is between the quantum dot light-emitting layer 102 and the electron transport layer 104. The preparation method and process of other film layers are the same as the first method.

### Method 7

In the seventh method, any one of the above methods 1, 2, 3 and 4 can be used to treat the quantum dot light-emitting layer, and the preparation method of the electron transport layer 104 is different from the first method. In the seventh method, when preparing the electron transport layer 104, an electron transport material ZnO with a first ligand comprising a basic group is deposited on the side of the quantum dot light-emitting layer 102 away from the first electrode 101, and the basic group on the first ligand react with the excess organic acid groups on the surface of the quantum dot light-emitting layer 102 to form a salt layer, i.e., a protective layer 203. The alkaline material can be, for example, an organic base or a lewis base. The preparation method and process of other film layers are the same as the first method.

The general chemical formula of the first ligand of ZnO is

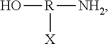

the first ligand may be, for example, an alcohol amine substance. In this general chemical formula, the group R represents an alkyl chain, and the group X may be the structure

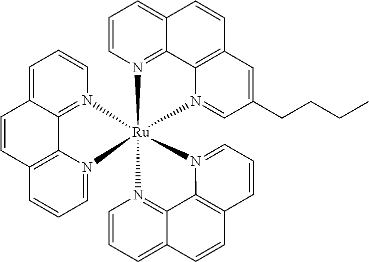

shown in FIG. 8, the structure

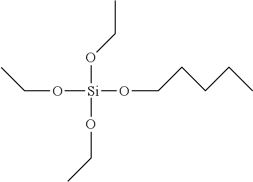 [SMILES: CCCCCO[Si](OCC)(OCC)OCC]

shown in FIG. 9, the structure

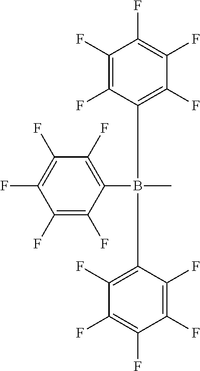

shown in FIG. 10 or the structure

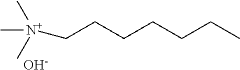

shown in FIG. 11.

In some embodiments, the electron transport layer 104 comprises a first surface close to the quantum dot light-emitting layer 102 and a second surface away from the quantum dot light-emitting layer 102, and the salt layer (i.e., the protective layer 203) is connected with the first coordination groups at the first surface through chemical bonds. This is because, in the preparation stage, the basic groups on the first ligands on the first surface of the electron transport layer 104 close to the quantum dot light-emitting layer 102 generally react with the excess organic acid groups on the quantum dot light-emitting layer 102 to form a salt layer, so the salt layer is generally connected with the first coordination groups on the first surface. However, the basic groups on the first ligands on the second surface of the electron transport layer 104 away from the quantum dot light-emitting layer 102 usually do not participate in the reaction, so the basic groups are still connected to the first ligands on the second surface.

In some embodiments, the electron transport layer 104 comprises a first electron transport layer 1041, a second electron transport layer 1042 and a third electron transport layer 1043. The quantum dot light-emitting layer comprises a red quantum dot light-emitting layer, a green quantum dot light-emitting layer, and a blue quantum dot light-emitting layer, and an orthographic projection of the first electron transport layer 1041 on the first electrode 101 at least partially overlaps with an orthographic projection of the red quantum dot light-emitting layer on the first electrode 101, an orthographic projection of the second electron transport layer 1042 on the first electrode 101 at least partially overlaps with an orthographic projection of the green quantum dot light-emitting layer on the first electrode 101, and an orthographic projection of the third electron transport layer 1043 on the first electrode 101 at least partially overlaps with an orthographic projection of the blue quantum dot light-emitting layer on the first electrode 101. Depositing an electron transport material ZnO with a first ligand comprising a basic group on the side of the quantum dot light-emitting layer 102 away from the first electrode 101, comprises: depositing the first electron transport material, the second electron transport material and the third electron transport material on the side of the quantum dot light-emitting layer 102 away from the first electrode 101 to form a first electron transport layer 1041, a second electron transport layer 1042 and a third electron transport layer 1043 respectively, wherein the ratio of basic groups to first ligands in the first electron transport material ZnO is a first molar ratio, the ratio of basic groups to first ligands in the second electron transport material ZnO is a second molar ratio, and the ratio of basic groups to first ligands in the third electron transport material ZnO is a third molar ratio, the first molar ratio is greater than the second molar ratio, and the second molar ratio is greater than the third molar ratio.

For the protective layer 203 formed in this way, the amount of salt in the first protective layer 2031 corresponding to the red subpixel>the amount of salt in the second protective layer 2032 corresponding to the green subpixel>the amount of salt in the third protective layer 2033 corresponding to the blue subpixel, In this way, it can be achieved that the electron blocking effect of the first protective layer 2031>the electron blocking effect of the second protective layer 2032>the electron blocking effect of the third protective layer 2033, which is conducive to enhancing the electron blocking effect at the red subpixel.

The protective layer 203 formed by the seventh method is not only between the quantum dot light-emitting layer 102 and the electron transport layer 104, but also inside the electron transport layer 104. The protective layer 203 is in chemical contact with the electron transport layer 104, and the protective layer 203 can be attached to the end of the first ligand.

### Method 8

In the eighth method, any one of the above-mentioned methods 1, 2, 3 and 4 can be used to treat the quantum dot light-emitting layer, and the formation method of the protective layer 303 and the electron transport layer 104 is different from the first method. In the eighth method, firstly, an electron transport material ZnO is encapsulated with a surfactant, and then the electron transport material ZnO encapsulated with the surfactant is deposited on the side of the quantum dot light-emitting layer 102 away from the first electrode 101 to form an electron transport layer 104, wherein the surfactant acts as a protective layer 303. In this case, the surfactant may encapsulate ZnO nanoparticles from between the electron transport layer 104 and the quantum dot light-emitting layer 102, or may encapsulate ZnO nanoparticles from all sides of the electron transport layer 104. Alternatively, a surfactant layer may be formed on the side of the quantum dot light-emitting layer 102 away from the first electrode 101, and the surfactant layer acts as the protective layer 303, and then the electron transport layer 104 may be formed on the side of the protective layer 303 away from the first electrode 101. In this case, the surfactant may encapsulate the electron transport layer 104 from between the electron transport layer 104 and the quantum dot light-emitting layer 102, or encapsulate the electron transport layer 104 from all sides. The surfactant may form a vesicle-like structure to encapsulate ZnO in the electron transport layer 104. While protecting ZnO from the influence of organic acid groups, they can also increase the distance between ZnO particles, reduce electron injection and reduce conductivity, which is beneficial to charge balance.

In some embodiments, the general chemical formula of the surfactant may be expressed as A⁺B⁻, where A⁺ represents cation and B⁻ represents anion. For example, B⁻ may be selected from any one of halogen ions, hydroxide ions, PF₆⁻ and BF₄⁻, and the general chemical formula of A⁺ may be expressed as CₙH₂ₙ₊₁N(CₘH₂ₘ₊₁)₃ or CₙH₂ₙ₊₁N(CₘH₂ₘ₊₁)₂(CₘH₂ₘ₊₁)₂NCₙH₂ₙ₊₁, where n is any positive integer between 8 and 20, and m is any positive integer between 0 and 4. CₙH₂ₙ₊₁N(CₘH₂ₘ₊₁)₃ may be a cation of quaternary amine salt or a cation of quaternary amine base, which contains one N atom and is a single-center ion; CₙH₂ₙ₊₁N(CₘH₂ₘ₊₁)₂(CₘH₂ₘ₊₁)₂NCₙH₂ₙ₊₁ may be a cation of quaternary amine salt or a cation of quaternary amine base, which contains two N atoms and is a bicentric ion. Surfactant molecules are quaternary amine salts or quaternary amine bases molecules containing non-polar long-chain end.

For other technical effects of the manufacturing method of the light-emitting device, reference can be made to the technical effects of the light-emitting device described in the previous embodiment, and for the sake of brevity, the description will not be repeated here.

It will be understood that although the terms first, second, third, etc. may be used herein to describe various elements, compositions, regions, layers and/or portions, these elements, compositions, regions, layers and/or portions should not be limited by these terms. These terms are only used to distinguish an element, composition, region, layer or portion from another element, composition, region, layer or portion. Thus, a first element, composition, region, layer or portion discussed above could be termed a second element, composition, region, layer or portion without departing from the teachings of the present disclosure.

Spatially relative terms such as “row”, “column”, “below”, “above”, “left”, “right”, etc. may be used herein for ease of description to describe factors such as the relationship of an element or feature to another element(s) or feature(s) illustrated in the figures. It will be understood that these spatially relative terms are intended to encompass different orientations of the device in use or operation in addition to the orientation depicted in the figures. For example, if the device in the figures is turned over, elements described as “below” other elements or features would then be oriented “above” other elements or features. Thus, the exemplary term “below” can encompass both an orientation of above and below. The device may be otherwise oriented (rotated 90 degrees or at other orientations) and the spatially relative descriptors used herein are interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to limit the present disclosure. As used herein, the singular forms “a,” “an,” and “the” are intended to comprise the plural forms as well, unless the context clearly dictates otherwise. It will be further understood that the terms “comprise” and/or “include” when used in this specification designate the presence of stated features, integers, steps, operations, elements and/or parts, but do not exclude the presence or addition of one or more other features, integers, steps, operations, elements, compositions and/or groups thereof. As used herein, the term “and/or” comprises any and all combinations of one or more of the associated listed items. In the description of this specification, description with reference to the terms “an embodiment,” “another embodiment,” etc. means that a particular feature, structure, material, or characteristic described in connection with the embodiment is included in at least one embodiment of the present disclosure. In this specification, schematic representations of the above terms are not necessarily directed to the same embodiment or example. Furthermore, the particular features, structures, materials or characteristics described may be combined in any suitable manner in any one or more embodiments or examples. Furthermore, those skilled in the art may combine the different embodiments or examples as well as the features of the different embodiments or examples described in this specification without conflicting each other.

It will be understood that when an element or layer is referred to as being “on”, “connected to”, “coupled to”, or “adjacent to” another element or layer, it may be directly on, directly connected to, directly coupled to, or directly adjacent to another element or layer, or intervening elements or layers may be present. In contrast, when an element is referred to as being “directly on”, “directly connected to”, “directly coupled to”, “directly adjacent to” another element or layer, with no intervening elements or layers present. However, in no case should “on” or “directly on” be interpreted as requiring a layer to completely cover the layer below.

Embodiments of the disclosure are described herein with reference to schematic illustrations (and intermediate structures) of idealized embodiments of the disclosure. As such, variations to the shapes of the illustrations are to be expected, e.g., as a result of manufacturing techniques and/or tolerances. Accordingly, embodiments of the present disclosure should not be construed as limited to the particular shapes of the regions illustrated herein, but are to comprise deviations in shapes due, for example, to manufacturing. Thus, the regions illustrated in the figures are schematic in nature and their shapes are not intended to illustrate the actual shape of a region of a device and are not intended to limit the scope of the present disclosure.

Unless otherwise defined, all terms (comprising technical and scientific terms) used herein have the same meaning as commonly understood by one of ordinary skill in the art to which this disclosure belongs. It will be further understood that terms such as those defined in commonly used dictionaries should be construed to have meanings consistent with their meanings in the relevant art and/or the context of this specification, and will not be idealized or overly interpreted in a formal sense, unless expressly defined as such herein.

As will be appreciated by those skilled in the art, although the steps of the methods of the present disclosure are depicted in a particular order in the figures, this does not require or imply that the steps must be performed in that particular order, unless the context clearly dictates otherwise. Additionally or alternatively, multiple steps may be combined into one step for execution, and/or one step may be decomposed into multiple steps for execution. Furthermore, other method steps may be inserted between the steps. The inserted steps may represent such as improvements of a method described herein, or may be unrelated to the method. Also, a given step may not be fully complete before the next step starts.

“At least one of A, B, and C” has the same meaning as” at least one of A, B, or C″ and both include the following combinations of A, B, and C: only A, only B, only C, combinations of A and B, combinations of A and C, combinations of B and C, and combinations of A, B, and C.

A and/or B “includes the following three combinations: only A, only B, and a combination of A and B.

As used herein, “about”, “roughly” or “approximately” includes the stated value and an average value within an acceptable deviation range of a specific value, which is determined by a person of ordinary skill in the art in consideration of the measurement in question and the error (i.e., the limitations of the measurement system) associated with the measurement of a specific quantity.

The above descriptions are merely specific embodiments of the present disclosure, but the protection scope of the present disclosure is not limited thereto. Any changes or substitutions that those skilled in the art can easily think of within the technical scope disclosed by the present disclosure, should be comprised within the protection scope of the present disclosure. Therefore, the protection scope of the present disclosure should be based on the protection scope of the claims.

1. A light-emitting device comprising:
a first electrode;
a quantum dot light-emitting layer;
an electron transport layer on a side of the quantum dot light-emitting layer away from the first electrode; and
a protective layer on the side of the quantum dot light-emitting layer away from the first electrode,
wherein the quantum dot light-emitting layer comprises organic acid groups, and the protective layer blocks the organic acid groups from contacting with the electron transport layer.

2. The light-emitting device according to claim 1, wherein the protective layer is at least between the quantum dot light-emitting layer and the electron transport layer.

3. The light-emitting device according to claim 2, wherein the protective layer is further in the electron transport layer.

4. The light-emitting device according to claim 3, wherein the protective layer is in a side of the electron transport layer close to the quantum dot light-emitting layer, and the protective layer is in contact with the quantum dot light-emitting layer.

5. The light-emitting device according to claim 2, wherein the protective layer comprises an anti-contact layer or a salt layer, the salt layer comprises a carboxylate layer or a quaternary amine salt layer, and a material of the anti-contact layer comprises any one of a hydrophobic material, a silane coupling agent and an epoxy resin.

6. (canceled)

7. (canceled)

8. (canceled)

9. The light-emitting device according to claim 5, wherein the salt layer is in physical contact with the electron transport layer, or
wherein the salt layer is connected with the electron transport layer through a chemical bond.

10. (canceled)

11. The light-emitting device according to claim 9, wherein the electron transport layer comprises a ZnO body and a first coordination group coordinated on the ZnO body, and the salt layer is connected with at least some first coordination groups through the chemical bond, and
wherein the electron transport layer comprises a first surface close to the quantum dot light-emitting layer and a second surface away from the quantum dot light-emitting layer, the salt layer is connected with the first coordination group at the first surface through the chemical bond, and the second surface comprises a first ligand coordinated on the ZnO body, and the first ligand comprises a basic group.

12. (canceled)

13. The light-emitting device according to claim 11, wherein a general chemical formula of the first ligand is 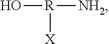
wherein the group R represents an alkyl chain, and the group X is selected from any one of the following:

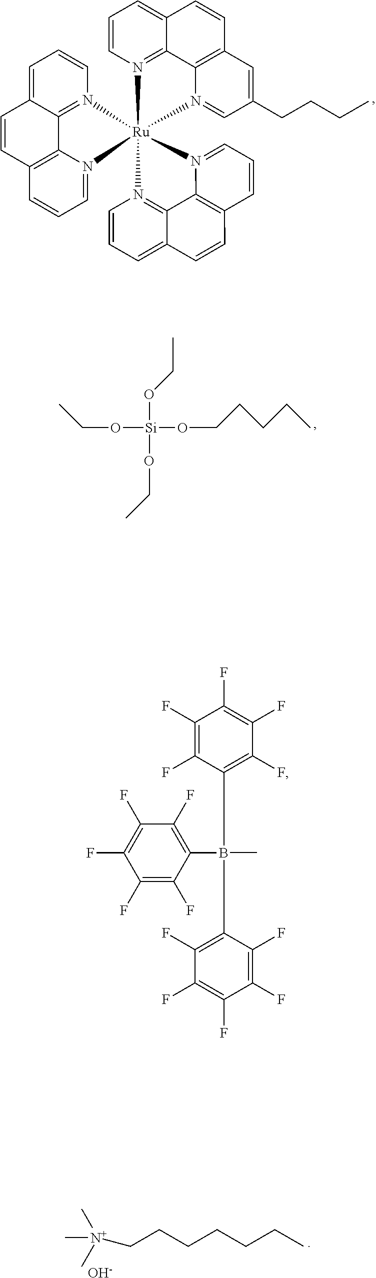

14. The light-emitting device according to claim 1, wherein the protective layer comprises a surfactant, and the surfactant encapsulates the electron transport layer, or
wherein the electron transport layer comprises zinc oxide nanoparticles, and the protective layer comprises a surfactant, and the surfactant encapsulates the zinc oxide nanoparticles.

15. (canceled)

16. The light-emitting device according to claim 14, wherein a general chemical formula of the surfactant is A⁺B⁻, wherein A⁻ represents cation and B⁻ represents anion,
wherein B⁻ is selected from any one of halogen ions, hydroxide ions, PF₆⁻ and BF₄⁻; and
wherein a general chemical formula of A⁺ is CₙH₂ₙ₊₁N(CₘH₂ₘ₊₁)₃ or CₙH₂ₙ₊₁N (CₘH₂ₘ₊₁)₂(CₘH₂ₘ₊₁)₂NCₙH₂ₙ₊₁, where n is any positive integer between 8 and 20 and m is any positive number between 0 and 4.

17. The light-emitting device according to claim 1, wherein the quantum dot light-emitting layer comprises a plurality of quantum dots, at least some quantum dots of the plurality of quantum dots each comprise a quantum dot body and a second ligand coordinated on the quantum dot body, and at least some second ligands are the organic acid groups, and wherein a general chemical formula of the organic acid groups is CₙCH₂ₙ₋₁COOH or C₆H₅—CₙH₂ₙ—COOH, and n is a positive integer greater than or equal to 1.

18. (canceled)

19. (canceled)

20. The light-emitting device according to claim 1, wherein the quantum dot light-emitting layer comprises a plurality of quantum dots, at least some quantum dots of the plurality of quantum dots each comprise a quantum dot body and a plurality of second ligands coordinated on the quantum dot body, a part of the second ligands in the plurality of second ligands are the organic acid groups, and the quantum dot light-emitting layer comprises a red quantum dot light-emitting layer configured to emit red light, a green quantum dot light-emitting layer configured to emit green light, and a blue quantum dot light-emitting layer configured to emit blue light, wherein the red quantum dot light-emitting layer, the green quantum dot light-emitting layer, and the green quantum dot light-emitting layer are separated from each other, and
a molar ratio of the organic acid groups in the red quantum dot light-emitting layer to the plurality of second ligands in the red quantum dot light-emitting layer is smaller than a molar ratio of the organic acid groups in the green quantum dot light-emitting layer to the plurality of second ligands in the green quantum dot light-emitting layer, and the molar ratio of organic acid groups in the green quantum dot light-emitting layer to the plurality of second ligands in the green quantum dot light-emitting layer is smaller than a molar ratio of organic acid groups in the blue quantum dot light-emitting layer to the plurality of second ligands in the blue quantum dot light-emitting layer.

21. The light-emitting device according to claim 20, wherein the molar ratio of organic acid groups in the red quantum dot light-emitting layer to the plurality of second ligands in the red quantum dot light-emitting layer is 0.1%-10%,
the molar ratio of organic acid groups in the green quantum dot light-emitting layer to the plurality of second ligands in the green quantum dot light-emitting layer is 0.1%-20%,
the molar ratio of organic acid groups in the blue quantum dot light-emitting layer to the plurality of second ligands in the blue quantum dot light-emitting layer is 0.1%-60%.

22. The light-emitting device according to claim 20, wherein the protective layer is between the quantum dot light-emitting layer and the electron transport layer, and the protective layer comprises a first protective layer, a second protective layer and a third protective layer, and an orthographic projection of the first protective layer on the first electrode at least partially overlaps with an orthographic projection of the red quantum dot light-emitting layer on the first electrode, an orthographic projection of the second protective layer on the first electrode at least partially overlaps with an orthographic projection of the green quantum dot light-emitting layer on the first electrode, and an orthographic projection of the third protective layer on the first electrode at least partially overlaps with an orthographic projection of the blue quantum dot light-emitting layer on the first electrode, a thickness of the first protective layer is greater than a thickness of the second protective layer, and the thickness of the second protective layer is greater than a thickness of the third protective layer.

23. The light-emitting device according to claim 20, wherein the electron transport layer comprises a hydrophobic material or an alkaline material, the electron transport layer comprises a first electron transport layer, a second electron transport layer and a third electron transport layer, and an orthographic projection of the first electron transport layer on the first electrode at least partially overlaps with an orthographic projection of the red quantum dot light-emitting layer on the first electrode, an orthographic projection of the second electron transport layer on the first electrode at least partially overlaps with an orthographic projection of the green quantum dot light-emitting layer on the first electrode, an orthographic projection of the third electron transport layer on the first electrode at least partially overlaps with an orthographic projection of the blue quantum dot light-emitting layer on the first electrode, a content of hydrophobic material or alkaline material in the first electron transport layer is greater than a content of hydrophobic material or alkaline material in the second electron transport layer, and the content of hydrophobic material or alkaline material in the second electron transport layer is greater than a content of hydrophobic material or alkaline material in the third electron transport layer.

24. The light-emitting device according to claim 23, wherein the protective layer comprises a salt layer, the protective layer comprises a first protective layer, a second protective layer and a third protective layer, an orthographic projection of the first protective layer on the first electrode at least partially overlaps with the orthographic projection of the red quantum dot light-emitting layer on the first electrode, an orthographic projection of the second protective layer on the first electrode at least partially overlaps with the orthographic projection of the green quantum dot light-emitting layer on the first electrode, an orthographic projection of the third protective layer on the first electrode at least partially overlaps with the orthographic projection of the blue quantum dot light-emitting layer on the first electrode, an amount of salt in the first protective layer is greater than an amount of salt in the second protective layer, and the amount of salt in the second protective layer is greater than an amount of salt in the third protective layer.

25. (canceled)

26. A method of manufacturing a light-emitting device, comprising:
providing a first electrode;
treating an intermediate layer or a quantum dot solution with an organic acid to form a quantum dot light-emitting layer comprising organic acid groups;
forming an electron transport layer on a side of the quantum dot light-emitting layer away from the first electrode; and
forming a protective layer on a side of the quantum dot light-emitting layer away from the first electrode, wherein the protective layer blocks the organic acid group from contacting with the electron transport layer.

27. The method according to claim 26, wherein forming the protective layer on the side of the quantum dot light-emitting layer away from the first electrode comprises:
treating a surface of the quantum dot light-emitting layer with saturated steam containing an alkaline material, so that the alkaline material and excess organic acid groups on the surface of the quantum dot light-emitting layer have acid-base neutralization reaction to form a salt layer, or
providing an anti-contact layer on the side of the quantum dot light-emitting layer away from the first electrode, wherein a material of the anti-contact layer comprises any one of hydrophobic material, silane coupling agent and epoxy resin; or
providing an alkaline layer on the side of the quantum dot light-emitting layer away from the first electrode, wherein the alkaline layer and excess organic acid groups on the surface of the quantum dot light-emitting layer have acid-base neutralization reaction to form a salt layer.

28. (canceled)

29. The method according to claim 26, wherein forming the electron transport layer on the side of the quantum dot light-emitting layer away from the first electrode and forming the protective layer on the side of the quantum dot light-emitting layer away from the first electrode comprises:
doping an alkaline material into an electron transport material to form a mixed material, depositing the mixed material on the side of the quantum dot light-emitting layer away from the first electrode to form the electron transport layer, wherein the alkaline material in the mixed material and excess organic acid groups on the surface of the quantum dot light-emitting layer have acid-base neutralization reaction to form a salt layer; or
depositing an electron transport material with a first ligand comprising a basic group on the side of the quantum dot light-emitting layer away from the first electrode to form the electron transport layer, wherein the basic group on the first ligand and excess organic acid groups on the surface of the quantum dot light-emitting layer have acid-base neutralization reaction to form a salt layer; or
encapsulating an electron transport material with a surfactant, and depositing the electron transport material encapsulated with the surfactant on the side of the quantum dot light-emitting layer away from the first electrode to form the electron transport layer; or
forming the surfactant on the side of the quantum dot light-emitting layer away from the first electrode, and forming the electron transport layer on the side of the surfactant away from the first electrode,
wherein the protective layer comprises the surfactant.

30. (canceled)

31. The method according to claim 26, wherein forming the electron transport layer on the side of the quantum dot light-emitting layer away from the first electrode and forming the protective layer on the side of the quantum dot light-emitting layer away from the first electrode comprises:
encapsulating an electron transport material with a surfactant, and depositing the electron transport material encapsulated with the surfactant on the side of the quantum dot light-emitting layer away from the first electrode to form the electron transport layer; or
forming the surfactant on the side of the quantum dot light-emitting layer away from the first electrode, and forming the electron transport layer on the side of the surfactant away from the first electrode,
wherein the protective layer comprises the surfactant.

32. The method according to claim 26, wherein treating the intermediate layer or the quantum dot solution with the organic acid comprises:
forming the intermediate layer on the first electrode, the intermediate layer comprising quantum dots, and treating the intermediate layer with saturated steam comprising the organic acid to form the quantum dot light-emitting layer on the first electrode; or
forming the intermediate layer on the first electrode, the intermediate layer comprising quantum dots, applying an organic acid solution on a side of the intermediate layer away from the first electrode so that the intermediate layer is soaked by the organic acid solution, and removing the organic acid solution to form the quantum dot light-emitting layer on the first electrode; or
preparing the quantum dot solution, the quantum dot comprising a quantum dot body and a second ligand coordinated on the quantum dot body, replacing at least some of the second ligands with the organic acid groups by a ligand exchange mode to form a treated quantum dot solution, and depositing the treated quantum dot solution on the first electrode to form the quantum dot light-emitting layer; or
mixing the organic acid with the quantum dot solution, and depositing a mixed solution on the first electrode to form the quantum dot light-emitting layer.
